(19) United States
(12) Patent Application Publication
(10) Pub. No.: US 2025/0096531 A1
(43) Pub. Date: Mar. 20, 2025

(54) SURFACE EMITTING LASER, LASER DEVICE, DETECTION DEVICE, AND MOBILE OBJECT

(71) Applicants: Naoto JIKUTANI, Miyagi (JP); Kazuhiro HARASAKA, Miyagi (JP); Ryoichiro SUZUKI, Miyagi (JP)

(72) Inventors: Naoto JIKUTANI, Miyagi (JP); Kazuhiro HARASAKA, Miyagi (JP); Ryoichiro SUZUKI, Miyagi (JP)

(21) Appl. No.: 18/728,902

(22) PCT Filed: Dec. 14, 2022
(86) PCT No.: PCT/IB2022/062185

§ 371 Date: Jul. 15, 2024

(30) Foreign Application Priority Data
Jan. 27, 2022 (JP) 2022-011032

(51) Int. Cl. H01S 5/183; G01S 17/894; H01S 5/042; H01S 5/06; H01S 5/062; H01S 5/30; H01S 5/343

(52) U.S. Cl. CPC H01S 5/18311; G01S 17/894; H01S 5/04256; H01S 5/0614; H01S 5/06216; H01S 5/18347; H01S 5/18361; H01S 5/18383; H01S 5/3095; H01S 5/34313

(57) ABSTRACT

A surface emitting laser includes: multiple active layers; a resonator including a tunnel junction between the multiple active layers; multiple reflectors sandwiching the resonator between the multiple reflectors; and an electrode pair connected to a power supply device through which a current is injected into the multiple active layers. The surface emitting laser does not oscillate a laser beam during a current injection period in which the power supply device injects the current into the multiple active layers through the electrode pair; and oscillates the laser beam during a current decrease period after the current injection period. The current injected into the multiple active layers during the current decrease period is lower than the current injected into the multiple active layers during the current injection period.

### TECHNICAL FIELD

The present disclosure relates to a surface emitting laser, a laser device, a detection device, and a mobile object.

### BACKGROUND ART

In many applications, it is desirable that the pulse output of the laser be large, and a multi-junction structure has been proposed as a structure for improving the output (NPL 5). Further, applications involving a short pulse width as well as a high pulse output are expanding. One example is a time-of-flight (TOF) sensor. In the TOF sensor, a laser light source having a high pulse output and a short pulse width is useful to achieve high accuracy and long distance while satisfying the eye-safe criterion. This is because the average power, which is one of the eye-safe criteria, is a value converted from the peak output, the pulse width, and the duty ratio, and the shorter the pulse width of the optical pulse, the higher the allowable peak output.

Measures for reducing the width of a pulse to 1 ns or less include gain switching, Q-switching, and mode-locking. The gain switching is a measure for providing a pulse width of 100 ps or less by using a relaxation oscillation phenomenon. Merely controlling the pulse current can provide such a pulse width, and hence the configuration for the guide switching is simpler than that for the Q-switching or mode-locking.

### CITATION LIST

### Patent Literature

[PTL 1]

U.S. Pat. No. 8,934,514

[NPL 1]

H. Yamamoto, M. Asada and Y. Suematsu, “Electric-field-induced refractive index variation in quantum-well structure”, Electron. Lett., 21 p. p. 579-580 (1985)

[NPL 2]

H. Nagai, M. Yamanishi, Y. Kan and I. Suemune, “Field-induced modulation of refractive index and absorption coefficient in a GaAs/AlGaAs quantum well structure”, Elect. Lett., 22 p. p. 888-889 (1986)

[NPL 3]

Nagai, M. Yamanishi, Y. Kan, I. Suemune, Y. Ide and R. Lang, “Excitation-induced dispersion of electroreflectance in a GaAs/AlAs quantum well structure at room temperature”, Extended abstract of the 18th conference on Solid State Devices and Materials, p. p. 591-594 (1986).

[NPL 4]

J. S. Weiner, D. A. B. Miller and D. S. Chemla, “Quadratic electro-optics effect due to the quantum confined Stark effect in quantum wells”, Appl. Phys. Lett., 50, 13, p. p. 842-844 (1987)

[NPL 5]

K. J. Ebeling; M. Grabherr; R. Jager; R. Michalzik, “Diode cascade quantum well VCSEL”, 1997 Digest of the IEEE/LEOS Summer Topical Meeting: Vertical-Cavity Lasers, WB1, p. p. 61, 1997

### SUMMARY OF INVENTION

### Technical Problem

The inventors of the present invention have found an issue that even if gain switching is applied to a surface-emitting laser having a conventional multi-junction structure, achieving both a high pulse output and a short pulse width is difficult due to variations in oscillation characteristics from multiple well layers.

An object of the present disclosure is to provide a surface-emitting laser, a laser device, a detection device, and a mobile object that achieves both a high pulse output and a short pulse width.

### Solution to Problem

An embodiment of the present disclosure provides a surface emitting laser including: multiple active layers; a resonator including a tunnel junction between the multiple active layers; multiple reflectors sandwiching the resonator between the multiple reflectors; and an electrode pair connected to a power supply device through which a current is injected into the multiple active layers. The surface emitting laser does not oscillate a laser beam during a current injection period in which the power supply device injects the current into the multiple active layers through the electrode pair; and oscillates the laser beam during a current decrease period after the current injection period. The current injected into the multiple active layers during the current decrease period is lower than the current injected into the multiple active layers during the current injection period.

### Advantageous Effects of Invention

The technologies according to embodiments of the present disclosure achieve both a high pulse output and a short pulse width.

### BRIEF DESCRIPTION OF DRAWINGS

The accompanying drawings are intended to depict example embodiments of the present invention and should not be interpreted to limit the scope thereof. The accompanying drawings are not to be considered as drawn to scale unless explicitly noted. Also, identical or similar reference numerals designate identical or similar components throughout the several views.

FIG. 1 is a band diagram illustrating a tunnel junction.

FIG. 2 is a band diagram illustrating a tunnel junction used to connect multiple active layers.

FIG. 3 is a cross-sectional view of a surface emitting laser according to a first reference example.

FIG. 4 is a cross-sectional view of an oxidized confinement layer and the vicinity thereof according to the first reference example.

FIG. 5 is a cross-sectional view of an oxidized confinement layer and the vicinity thereof according to a second reference example.

FIG. 6 is an equivalent circuit diagram of a circuit used for actual measurement.

FIG. 7A is a graph presenting an actual measurement result of the second reference example.

FIG. 7B is a graph presenting an actual measurement result of the second reference example.

FIG. 7C is a graph presenting an actual measurement result of the second reference example.

FIG. 8A is a graph presenting an actual measurement result of the first reference example.

FIG. 8B is a graph presenting an actual measurement result of the first reference example.

FIG. 8C is a graph presenting an actual measurement result of the first reference example.

FIG. 9A is a graph presenting a difference in distributions of electric field intensity and equivalent refractive index depending on a structure.

FIG. 9B is a graph presenting a difference in distributions of electric field intensity and equivalent refractive index depending on a structure.

FIG. 10A is a graph presenting a change in distributions of electric field intensity and equivalent refractive index over time.

FIG. 10B is a graph presenting a change in distributions of electric field intensity and equivalent refractive index over time.

FIG. 11 is a graph presenting simulation results for carrier density and threshold carrier density according to the second reference example.

FIG. 12 is a graph presenting simulation results for optical output according to the second reference example.

FIG. 13 is a graph presenting an example of a function used in a simulation according to the first reference example.

FIG. 14 is a graph presenting simulation results for optical output according to the first reference example.

FIG. 15A is a graph presenting simulation results for carrier density, threshold carrier density, and photon density according to the first reference example.

FIG. 15B is a graph presenting a simulation result for optical confinement factor in a lateral direction according to the first reference example.

FIG. 16A is a partially enlarged graph of FIG. 15A.

FIG. 16B is a partially enlarged graph of FIG. 15B.

FIG. 17A is a graph presenting an example of an actual measurement result of optical pulses.

FIG. 17B is a graph presenting an example of a simulation result of optical pulses.

FIG. 18 is a cross-sectional view of a surface emitting laser according to a first embodiment.

FIG. 19 is a graph presenting the relation between the current confinement area and the peak optical output.

FIG. 20 is a cross-sectional view of a surface emitting laser according to a second embodiment.

FIG. 21 is a cross-sectional view of a surface emitting laser according to a third embodiment.

FIG. 22A is a top view of a surface emitting laser according to a fourth embodiment.

FIG. 22B is a cross-sectional view of a surface emitting laser according to the fourth embodiment.

FIG. 23 is a cross-sectional view of a surface emitting laser according to a fifth embodiment.

FIG. 24 is a cross-sectional view of a surface emitting laser according to a sixth embodiment.

FIG. 25 is a cross-sectional view of a surface emitting laser according to a seventh embodiment.

FIG. 26 is a cross-sectional view of a surface emitting laser according to an eighth embodiment.

FIG. 27 is a diagram illustrating a laser device according to a ninth embodiment.

FIG. 28 is a graph presenting the relation between the duty ratio and the peak output of optical pulses.

FIG. 29 is a diagram illustrating a distance measurement device according to a tenth embodiment.

FIG. 30 is a diagram of a mobile object according to an eleventh embodiment. [Description of Embodiments]

The terminology used herein is for the purpose of describing particular embodiments only and is not intended to be limiting of the present invention. As used herein, the singular forms “a,” “an,” and “the” are intended to include the plural forms as well, unless the context clearly indicates otherwise.

In describing embodiments illustrated in the drawings, specific terminology is employed for the sake of clarity. However, the disclosure of this specification is not intended to be limited to the specific terminology so selected and it is to be understood that each specific element includes all technical equivalents that have a similar function, operate in a similar manner, and achieve a similar result.

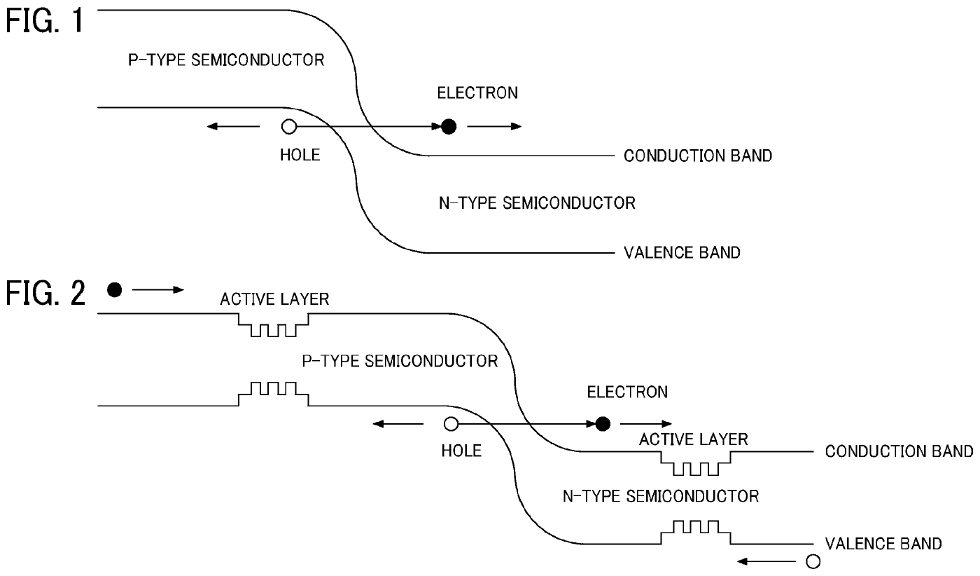

First, the multi-junction structure will be described. In the multi-junction structure, multiple active layers are provided with a tunnel junction between the multiple active layers. The tunnel junction is composed of a heavily doped p-n junction. When a reverse bias is applied to the p-n junction so that the conduction band energy of the n-type semiconductor becomes lower than the valence band energy of the p-type semiconductor as illustrated in FIG. 1, electrons can be tunneled from the valence band of the p-type semiconductor layer to the conduction band of the n-type semiconductor layer through the depletion layer. Then, holes are generated in the p-type semiconductor by tunneling of electrons. This allows electrons to be supplied to the n-type semiconductor and holes to be supplied to the p-type semiconductor through the tunnel junction.

In addition, as illustrated in FIG. 2, when a tunnel junction is used to connect multiple active layers, more well layers can be used without reducing the efficiency of carrier injection into the well layers, thus achieving high-efficiency and high-output operation. If the number of well layers is simply increased without using a tunnel junction, it is difficult to sufficiently inject a carrier having a large effective mass such as a hole into a well layer distant from the injection side. This results in failure to achieve a uniform carrier density between the well layer close to the injection side and the well layer distant from the injection side, and thus fails to achieve a higher output power. However, when a tunnel junction is used, electrons and holes can be generated to be used for injection. This allows uniform carrier injection irrespective of an increase in the number of well layers.

Further, since the same number of electrons as the number of electrons supplied from the power supply are generated in the tunnel junction due to the continuity of the current, one electron performs light emission recombination multiple times in each of the active layers with tunnel junctions therebetween. This allows slope efficiency to increase in proportion to the number of well layers.

As a result, a higher output can be obtained.

However, the inventors of the present invention have found through studies that a surface emitting laser having a multi-junction structure has difficulties as described below in attempting to obtain a laser beam having a short-pulse width.

The gain switching operation outputs a short pulse by using a relaxation oscillation phenomenon caused by an interaction between an electron system in an active layer and a photon system in a resonator, which occurs immediately after application of a drive current pulse, and is a transient phenomenon until a steady output of the pulse is reached. For this reason, the gain switch operation is basically unstable, and the oscillation characteristics are susceptible to variations due to factors such as various structures and characteristics. In other words, in order to obtain a high-output short pulse in the multi-junction structure, it is desirable that the respective active layer exhibits the same oscillation characteristics and are temporally synchronized with each other. However, it is difficult to obtain the same oscillation characteristics.

Specifically, main factors that determine the oscillation characteristics of the active layer are a gain constant, a transparent carrier density, the volume of each active layer, an injection efficiency, and the like, but it is difficult to obtain the same oscillation characteristics for each of multiple active layers provided in the resonator.

For example, since the active layer volume is determined by the spread of the currents injected, a change in the distance from the oxide confinement structure changes the spread of the currents injected and thus changes the volume of each active layer. The difference in the volume of each active layer causes a difference in carrier density when a drive current pulse is applied to the device. This results in a difference in active layer gain. The similar variations in oscillation characteristics occur in both variations in the thickness of the well layer and variations in the amount of strain in the strained quantum well.

In addition, since the tunnel junction included in the surface emitting laser is composed of a thin film, electrical characteristics such as resistance of the tunnel junction may vary due to variations in impurity concentration profile, and variation in carrier injection rate into the active layer may occur. With variations in the impurity concentration profile, the number of carriers and the carrier density at a certain time may vary between the multiple well layers. In such a situation, when the well layer that first reaches the oscillation threshold gain starts oscillation, the number of photons in the resonator rapidly increases, and the other well layers also start oscillation. At this time, the difference in the carrier density becomes a difference in the stimulated emission rate and affects the magnitude of the pulse width, and the difference in the number of carriers becomes a difference in the pulse output and affects the magnitude of the output. In particular, the variation in injection current at the time of applying a current pulse affects the variation in the number of carriers accumulated in each active layer and appears as the variation in pulse output at the time of oscillation, so that the variation in injection current significantly affects the output characteristics. In addition, in a surface-emitting laser element having a current injection region smaller than that of an edge-emitting laser, variations in the electrical characteristics of the tunnel junction are likely to become apparent. As described above, efficiently increasing output power in the conventional gain-switched surface-emitting laser is difficult.

### Reference Example

Reference examples related to the present disclosure will be described. In the specification and the drawings, components having substantially the same functional configuration are denoted by the same reference sign, and redundant description may be omitted.

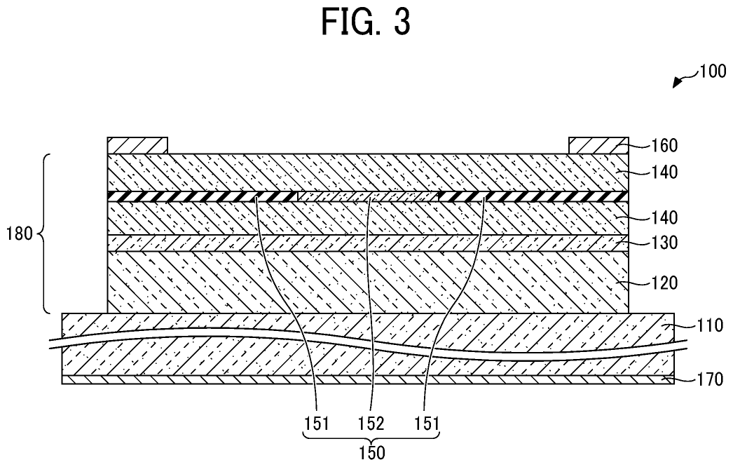

A first reference example is described. The first reference example relates to a surface emitting laser. FIG. 3 is a cross-sectional view illustrating a surface emitting laser 100 according to the first reference example.

The surface emitting laser 100 according to the first reference example is, for example, a vertical cavity surface emitting laser (VCSEL) using oxidation confinement. The surface emitting laser 100 includes an n-type GaAs substrate 110, an n-type distributed Bragg reflector (DBR) 120, an active layer 130, a p-type DBR 140, an oxidized confinement layer 150, an upper electrode 160, and a lower electrode 170.

In the first reference example, light is emitted in a direction perpendicular to a surface of the n-type GaAs substrate 110. Hereinafter, the direction perpendicular to the surface of the n-type GaAs substrate 110 may be referred to as a vertical direction, and the direction parallel to the surface of the n-type GaAs substrate 110 may be referred to as a lateral direction or an in-plane direction.

The n-type DBR 120 is on the n-type GaAs substrate 110. The n-type DBR 120 is, for example, a semiconductor multilayer-film reflecting mirror including a plurality of n-type semiconductor films stacked on one another. For example, the n-type DBR 120 includes multiple Al_{0.95}Ga_{0.05}As films and Al_{0.15}Ga_{0.85}As films. The active layer 130 is on the n-type DBR 120. The active layer 130 includes, for example, a plurality of quantum well layers and a plurality of barrier layers. The active layer 130 is included in the resonator. The p-type DBR 140 is on the active layer 130. The p-DBR 147 is, for example, a semiconducting multilayer reflector consisting of a plurality of p-type semiconductor films that are multilayered. For example, the p-type DBR 140 includes multiple pairs of Al_{0.95}Ga_{0.05}As films and Al_{0.15}Ga_{0.85}As films. The resonator further includes a spacer layer between the n-type DBR 120 and the active layer 130 and a spacer layer between the active layer 130 and the p-type DBR 140.

The upper electrode 160 is in contact with an upper surface of the p-type DBR 140 in plan view. The lower electrode 170 is in contact with a lower surface of the n-type GaAs substrate 110. The pair of the upper electrode 160 and the lower electrode 170 is an example of an electrode pair. However, the positions of the electrodes are not limited thereto, and may be any positions as far as the electrodes can inject current into the active layer. For example, an intracavity structure may be employed in which electrodes are directly disposed in a spacer layer of a resonator instead of via a DBR.

The p-type DBR 140 includes, for example, the oxidized confinement layer 150. The oxidized confinement layer 150 contains Al. The oxidized confinement layer 150 includes an oxidized region 151 and a non-oxidized region 152 in a plane perpendicular to the direction in which light is emitted (hereinafter, referred to as an emission direction of light). The oxidized region 151 has an annular planar shape and surrounds the non-oxidized region 152. The non-oxidized region 152 includes a p-type AlAs layer 155 and two p-type Al_{0.85}Ga_{0.15}As layers 156 that sandwich the p-type AlAs layer 155 in the vertical direction. The oxidized region 151 is made of AlOₓ. The refractive index of the oxidized region 151 is lower than the refractive index of the non-oxidized region 152. For example, the refractive index of the oxidized region 151 is 1.65, the refractive index of the p-type AlAs layer 155 is 2.96, and the refractive index of the p-type Al_{0.85}Ga_{0.15}As layers 156 is 3.04. In plan view, a portion of a mesa 180 inside an inner edge of the oxidized region 151 is an example of a high refractive index region, and a portion of the mesa 180 outside the inner edge of the oxidized region 151 is an example of a low refractive index region. In one example, p-type AlₓGa₁₋ₓAs layers (0.70≤x≤0.90) may be provided instead of the p-type Al_{0.85}Ga_{0.15}As layers 156. In the present embodiment, the p-type DBR 140, the active layer 130, and the n-type DBR 120 constitute the mesa 180. However, in the first reference example in which a current confinement region is formed by oxidation confinement, at least the oxidized confinement layer 150 and a semiconductor layer located above the oxidized confinement layer 150 are formed in a mesa shape. When at least the active layer is formed to be included in the mesa, light generated in the active layer can be prevented from leaking in the lateral direction.

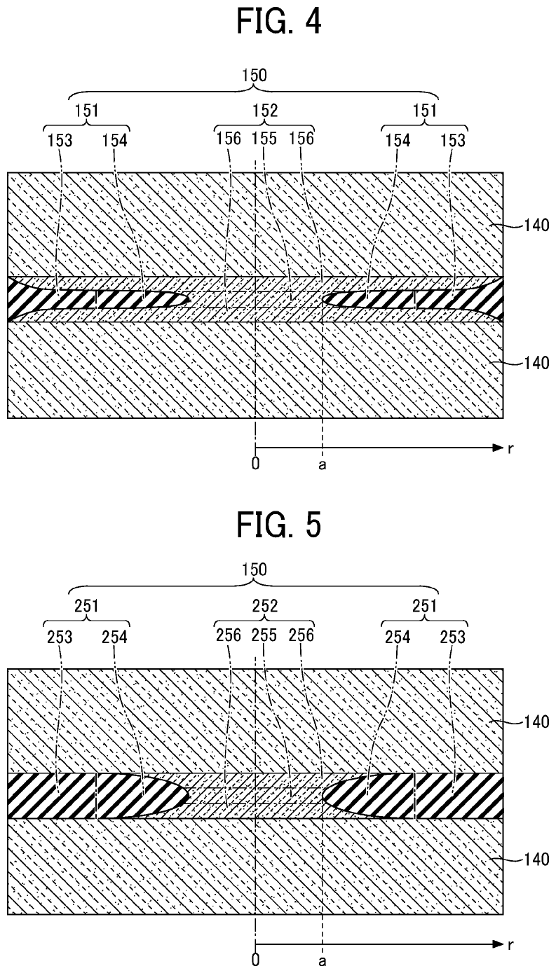

The oxidized confinement layer 150 is described in detail. FIG. 4 is a cross-sectional view illustrating an oxidized confinement layer and the vicinity thereof according to the first reference example.

As illustrated in FIG. 4, the oxidized region 151 has, in plan view, an annular outer region 153 and an annular inner region 154. The outer region 153 is exposed from a side surface of the mesa 180. The outer region 153 is a region in which the thickness changes so that the contact surface of the surface is located in an outer section of the oxidized region 151 in cross-sectional view. The inner region 154 is a region in which the thickness changes so that the contact surface of the surface is located in an inner section of the oxidized region 151 in cross-sectional view. The inner region 154 is located inside the outer region 153. The thickness of the inner region 154 matches the thickness of the outer region 153 at the boundary with the outer region 153, and decreases toward the center of the mesa 180. The inner region 154 has a tapered shape that is gradually thicker from the inner edge to the boundary with the outer region 153 in cross-sectional view. The non-oxidized region 152 is located inside the outer region 153. Portions of the non-oxidized region 152 sandwich the inner region 154 in the vertical direction. The other portion of the non-oxidized region 152 is located inside the inner edge of the inner region 154 in plan view. For example, the thickness of the non-oxidized region 152 is 35 nm or less. The thickness of the outer region 153 may be larger than the thickness of the non-oxidized region 152. In the embodiment of the present disclosure, the thickness of the non-oxidized region 152 is the thickness of a portion on the center side of the mesa 180 with respect to the inner edge of the oxidized region 151 (the inner edge of the inner region 154). For example, the distance from the side surface of the mesa 180 to the inner edge of the oxidized region 151 is in a range from about 8 μm to about 11 μm.

The oxidized region 151 is formed by, for example, oxidation confinement of a p-type AlAs layer and a p-type Al_{0.85}Ga_{0.15}As layer. For example, the oxidized region 151 can be formed by oxidizing the p-type AlAs layer and the p-type Al_{0.85}Ga_{0.15}As layer in a high-temperature water vapor environment. Even when the same p-type AlAs layer and the same p-type Al_{0.85}Ga_{0.15}As layer are oxidized, the structure of the oxidized confinement layer obtained from the p-type AlAs layer and the p-type Al_{0.85}Ga_{0.15}As layer may vary depending on the conditions of oxidation. Thus, even when the layers to be the oxidized confinement layer 150 by oxidation, for example, the p-type AlAs layer and the p-type Al_{0.85}Ga_{0.15}As layer have the same structures as those before oxidation, the oxidized confinement layer 150 including the oxidized region 151 and the non-oxidized region 152 is not obtained in some cases depending on the conditions of oxidation.

The advantageous effect of the first reference example is described in comparison with the second example. FIG. 5 is a cross-sectional view illustrating an oxidized confinement layer and the vicinity thereof according to the first reference example.

In the second reference example, the oxidized confinement layer 150 includes an oxidized region 251 and a non-oxidized region 252 instead of the oxidized region 151 and the non-oxidized region 152. The oxidized region 251 has an annular planar shape and surrounds the non-oxidized region 252. The non-oxidized region 252 includes a p-type AlAs layer 255 and two p-type Al_{0.85}Ga_{0.15}As layers 256 that sandwich the p-type AlAs layer 255 in the vertical direction. The oxidized region 251 has, in plan view, an annular outer region 253 and an annular inner region 254. The outer region 253 is exposed from a side surface of a mesa 180. The thickness of the outer region 253 is constant in the in-plane direction. The inner region 254 is located inside the outer region 253. The thickness of the inner region 254 matches the thickness of the outer region 253 at the boundary with the outer region 253, and decreases toward the center of the mesa 180. The inner region 254 has a tapered shape that is gradually thicker from an inner edge to the boundary with the outer region 253 in cross-sectional view. The non-oxidized region 252 is located inside the outer region 253. Portions of the non-oxidized region 252 sandwich the inner region 254 in the vertical direction. The other portion of the non-oxidized region 252 is located inside the inner edge of the inner region 254 in plan view. For example, the distance from the side surface of the mesa 180 to the inner edge of the oxidized region 251 is in a range from about 8 μm to about 11 μm. The thicknesses of the oxidized region 251 and the non-oxidized region 252 are equal to the thickness of the oxidized confinement layer 150.

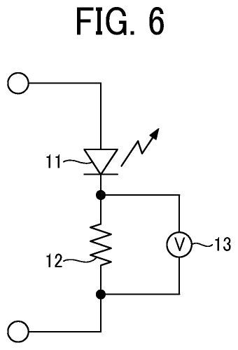

Actual measurement results according to the first reference example and the second reference example are described first. FIG. 6 is an equivalent circuit diagram of a circuit used for actual measurement.

In this circuit, a resistor 12 for monitoring current is coupled in series to a surface emitting laser 11 corresponding to the first reference example or the second reference example. A voltmeter 13 is coupled in parallel to the resistor 12. Light output from the surface emitting laser 11 was received by a wide-band high-speed photodiode and converted into a voltage signal. The voltage signal was observed with an oscilloscope.

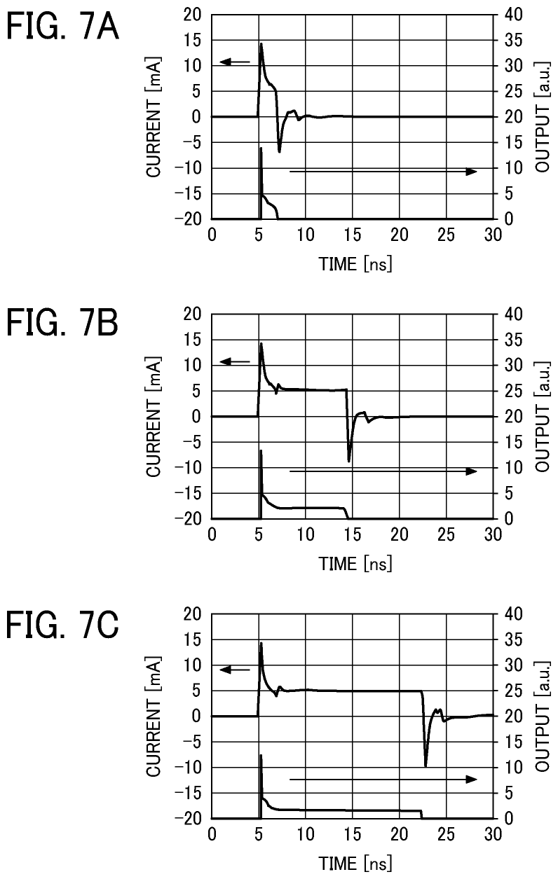

FIGS. 7A to 7C are graphs presenting actual measurement results of the second reference example. FIG. 7A presents an actual measurement result when the width of pulse current is about 2 ns. FIG. 7B presents an actual measurement result when the width of pulse current is about 9 ns. FIG. 7C presents an actual measurement result when the width of pulse current is about 17 ns. In the actual measurement in FIGS. 7A to 7C, the magnitude of bias current and the amplitude of pulse current are common. FIGS. 7A to 7C each present current flowing through the resistor 12 and an optical output measured by the high-speed photodiode. The current flowing through the resistor 12 can be calculated using the voltmeter 13.

As presented in FIGS. 7A to 7C, in the second reference example, regardless of the magnitude of the width of pulse current, an optical pulse is output immediately after the pulse current is injected, then an equilibrium state is established until the injection of the pulse current is stopped, and constant tail light is output. The leading optical pulse is caused by relaxation oscillation, which is typical driving by gain switching. Even when the pulse width is changed, the timing at which the optical pulse is generated does not change. This is because the optical pulse generated by the relaxation oscillation is generated immediately after the carrier density in the laser resonator exceeds the threshold carrier density. To reduce the output of tail light, the current injection may be stopped immediately after the optical pulse is output. However, since the time width of the optical pulse caused by the relaxation oscillation is 100 ps or less, when the magnitude of the current is as large as 10 A or more, it is difficult to stop the injection of the current in a period of 100 ps or less immediately after the optical pulse is output.

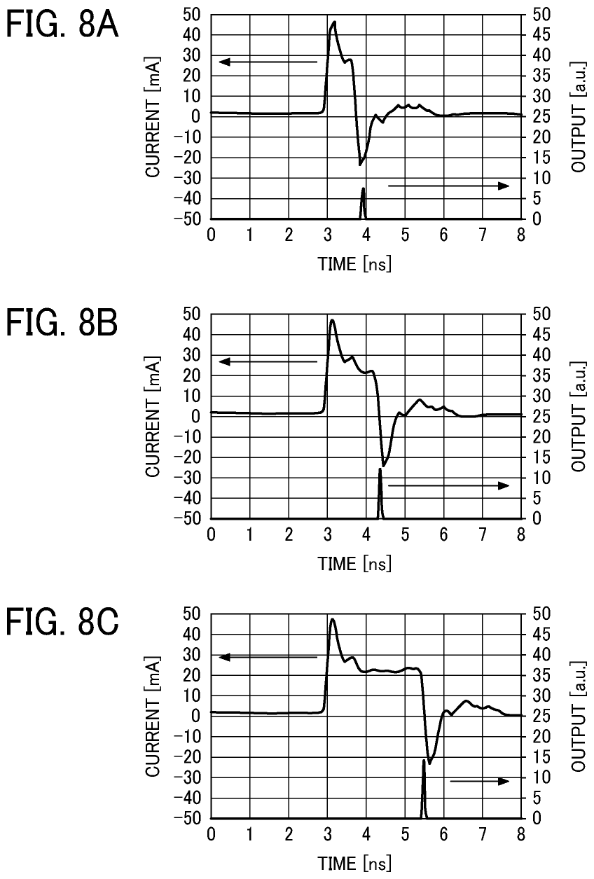

FIGS. 8A to 8C are graphs presenting actual measurement results of the first reference example. FIG. 8A presents an actual measurement result when the width of pulse current is about 0.8 ns. FIG. 8B presents an actual measurement result when the width of pulse current is about 1.3 ns. FIG. 8C presents an actual measurement result when the width of pulse current is about 2.5 ns. In the actual measurement in FIGS. 8A to 8C, the magnitude of bias current and the amplitude of pulse current are common. FIGS. 8A to 8C each present current flowing through the resistor 12 and an optical output measured by the high-speed photodiode. The current flowing through the resistor 12 can be calculated using the voltmeter 13.

As presented in FIGS. 8A to 8C, in the first reference example, an optical output is not generated in a state in which pulse current is injected, and an optical pulse is output immediately after the injection of the pulse current decreases. Moreover, tail light after the optical pulse is output is almost not observed. In the case of the optical output by gain switching, the timing at which the optical pulse is generated does not change even when the width of the pulse current is changed. In contrast, according to the first reference example, the optical pulse is output when the injection of the pulse current decreases. Thus, the optical output according to the first reference example is not based on normal gain switching using the relaxation oscillation phenomenon.

As described above, the first reference example and the second reference example clearly differ from each other in the mechanism and manner of the optical output. The difference is described as follows.

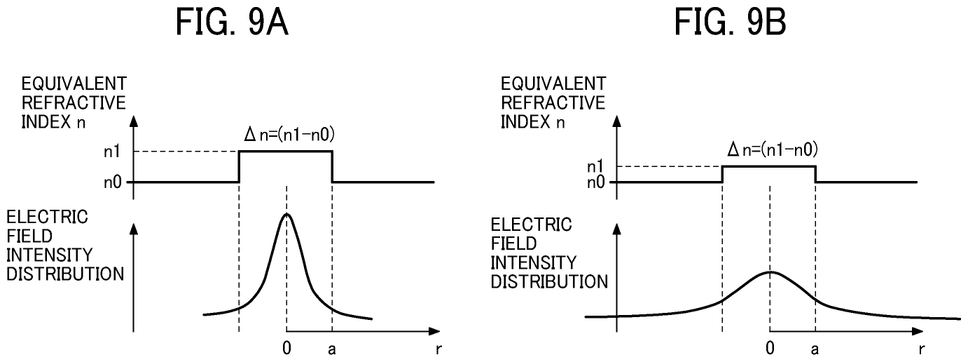

In a surface emitting laser, a laser beam propagates in a resonator in a direction perpendicular to an oxidized confinement layer. Thus, as the oxidized confinement layer is thicker, an equivalent waveguide length dependent on the difference in refractive index increases, and an optical confinement effect in the lateral direction increases. When a DBR including the oxidized confinement layer is considered as an equivalent waveguide structure, the electric field intensity distribution of laser beams is concentrated around the center when the difference in equivalent refractive index is large as presented in FIG. 9A. In contrast, when the difference in equivalent refractive index is small as presented in FIG. 9B, the electric field intensity distribution of laser beams expands to the oxidized region in the periphery. When the first reference example is compared with the reference second example, since the oxidized confinement layer 150 includes the inner region 154 in the first embodiment, the difference in equivalent refractive index decreases in the first reference example. Thus, the electric field intensity distribution of the laser beams is concentrated around the center in the second reference example as presented in FIG. 9A. In contrast, the electric field intensity distribution of the laser beams expands to the oxidized region 151 in the first reference example as presented in FIG. 9B.

In this case, an optical confinement factor in the lateral direction is defined as a ratio of “an integrated intensity of an electric field in a region having the same radius as a current passing region” to “an integrated intensity of an electric field in a lateral cross-section passing through the center of a surface emitting laser element”, and is expressed by Equation (1). In this case, a corresponds to a radius of the current passing region, and Φ represents a rotation direction around a rotation axis in the direction perpendicular to the substrate.

$$[ Equation 1 ]$$

$${Γ}_{r} = \frac{{\int }_{0}^{a} {\int }_{0}^{2 π} {\vert E \vert}^{2} \cdot rd Φ dr}{{\int }_{0}^{∞} {\int }_{0}^{2 π} {\vert E \vert}^{2} \cdot rd Φ dr} \qquad ( 1 )$$

A model of a phenomenon that occurs when injection of pulse current is stopped is described next. In a state in which the pulse current is injected, the current path is concentrated around the center of the mesa by the oxidized confinement layer, and the carrier density is high. At this time, an effect of decreasing the refractive index is generated by a carrier plasma effect in the non-oxidized region having a high carrier density. The carrier plasma effect is a phenomenon in which the refractive index decreases in proportion to a free carrier density. Referring to, for example, Kobayashi, Soichi, et al., “Direct Frequency Modulation in AlGaAs Semiconductor Lasers”, IEEE Transactions on Microwave Theory and Techniques, Volume 30, Issue 4, 1982, pp. 428-441, the amount of change in refractive index is expressed by Equation (2). In this case, N is a carrier density.

$$[ Equation 2 ]$$

$$Δ n \approx - 4 \times {10}^{- 21} [ {cm}^{3} ] \times N [ 1 / {cm}^{3} ] \qquad ( 2 )$$

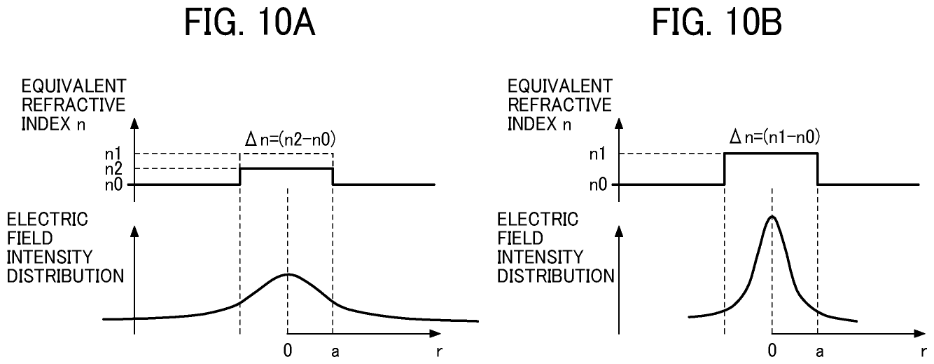

FIG. 10A schematically presents an equivalent refractive index and an electric field intensity distribution in a period in which pulse current is injected. FIG. 10B schematically presents an equivalent refractive index and an electric field intensity distribution in a period in which the injection of the pulse current is stopped and the pulse current decreases. The carrier plasma effect acts in a direction to cancel out the equivalent refractive-index difference (n1−n0) generated by the oxidized confinement layer in the period in which the pulse current is injected, and hence the equivalent refractive-index difference is (n2−n0). When the injection of the pulse current decreases in this state, the carrier plasma effect no longer acts, and the equivalent refractive-index difference returns to (n1−n0). Thus, photons that have spread to the peripheral portion of the mesa are concentrated in the center portion of the mesa, and the photon density in the non-oxidized region increases. That is, the state changes to a state in which lateral optical confinement is strong. When the injection of the pulse current is stopped, carriers accumulated in the resonator decrease over the carrier lifetime. However, when the lateral optical confinement increases before the carrier density completely attenuates, induced emission starts, the accumulated carriers are consumed at once, and an optical pulse is output. The period in which the pulse current is injected is an example of a current injection period, and the period in which the injection of the pulse current is stopped and the pulse current decreases is an example of a current decrease period.

The results of verification of the above-described model through a simulation are described below. The rate equations of the carrier density and the photon density are expressed in Equations (3) and (4).

$$[ Equation 3 ]$$

$$\frac{dN}{dt} = \frac{i ( t )}{eV} - \frac{N}{{τ}_{n} ( N )} - {v}_{g} g ( N , S ) S \qquad ( 3 )$$

$$[ Equation 4 ]$$

$$\frac{dS}{dt} = ( {Γ}_{a} {v}_{g} g ( N , S ) - \frac{1}{{τ}_{p}} ) S + \frac{{Γ}_{a} β N}{{τ}_{n} ( N )} \qquad ( 4 )$$

The content indicated by each character in Equations (3) and (4) is as follows.
N denotes a carrier density (1/cm³),
S denotes a photon density (1/cm³),
i(t) denotes injection current (A),
e denotes an elementary charge (C),
V denotes a resonator volume (cm³),
τₙ(N) denotes a carrier lifetime(s),
v_{g} denotes a group velocity (cm/s),
g(N, S) denotes a gain (1/cm),
Γₐ denotes an optical confinement factor,
τₚ denotes a photon lifetime(s),
β denotes a spontaneous emission coupling factor,
g₀ denotes a gain factor (1/cm),
ε denotes a gain suppression factor,
Nₜᵣ denotes a transparency carrier density (1/cm³),
ηᵢ denotes a current injection efficiency,
αₘ denotes a resonator mirror loss (1/cm),
h denotes the Planck constant (Js), and
ν denotes a frequency of light (1/s).

The gain g(N, S) is given by Equation (5).

$$[ Equation 5 ]$$

$$g ( N , S ) = \frac{{g}_{0}}{1 + ε S} ln \frac{N}{{N}_{tr}} \qquad ( 5 )$$

As expressed in Equation (6), the optical confinement factor Γₐ is defined by the product of an optical confinement factor Γᵣ in the lateral direction and an optical confinement factor Γ_{z} in the vertical direction.

$$[ Equation 6 ]$$

$${Γ}_{a} = {Γ}_{r} \times {Γ}_{z} \qquad ( 6 )$$

A threshold carrier density Nₜₕ is given by Equation (7).

$$[ Equation 7 ]$$

$${N}_{th} = {N}_{tr} \cdot exp ( \frac{1}{{Γ}_{a} \cdot {g}_{0} \cdot {v}_{g} \cdot {τ}_{p}} ) \qquad ( 7 )$$

A threshold current Iₜₕ and the threshold carrier density Nₜₕ have a relationship given by Equation (8).

$$[ Equation 8 ]$$

$$\frac{{η}_{i} \cdot {I}_{th}}{e \cdot V} = \frac{{N}_{th}}{{τ}_{n} ( N )} \qquad ( 8 )$$

An optical output P that is output from the resonator and the photon density S have a relationship given by Equation (9).

$$[ Equation 9 ]$$

$$P = {v}_{g} \cdot {α}_{m} \cdot S \cdot hv \cdot \frac{V}{{Γ}_{a}} \qquad ( 9 )$$

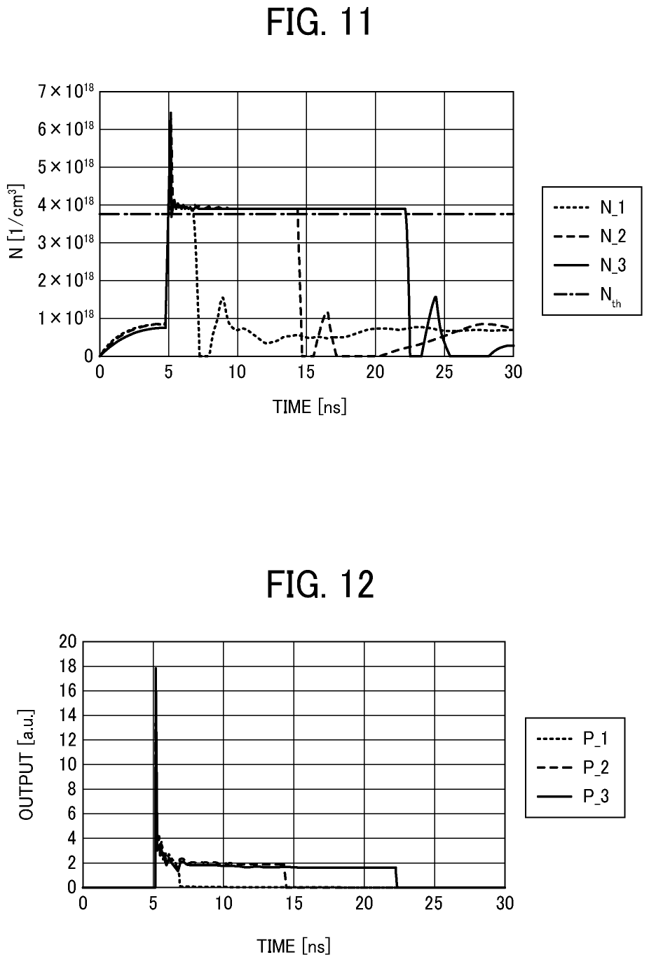

Simulation results according to the second reference example are described. For the second reference example, a simulation was performed with inputs of the current monitor waveforms presented in FIGS. 7A to 7C while the optical confinement factor Γᵣ in the lateral direction was 1. FIG. 11 presents simulation results for the carrier density N and the threshold carrier density Nₜₕ. FIG. 12 presents simulation results for the optical outputs.

As presented in FIGS. 11 and 12, at the time point of about 5 ns at which the pulse current is injected, the carrier density N exceeds the threshold carrier density Nun immediately thereafter, and an optical pulse caused by the relaxation oscillation is output. Then, an equilibrium state is established and constant tail light is output. As described above, in the simulation, results close to the actual measurement results presented in FIGS. 7A to 7C are obtained.

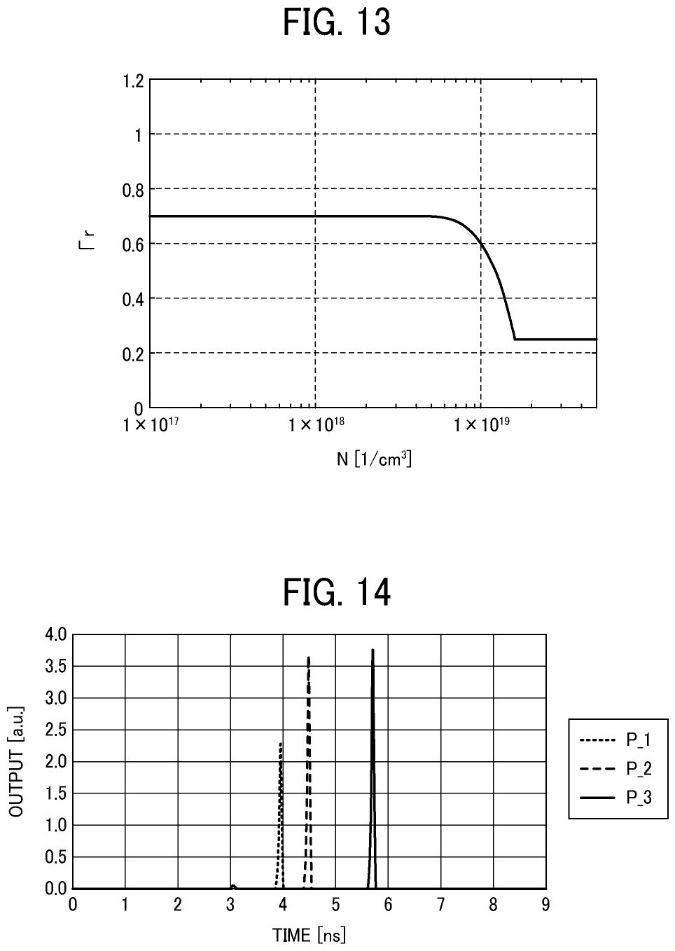

Simulation results according to the first reference example are described. For the first reference example, a simulation was performed with inputs of the current monitor waveforms presented in FIGS. 8A to 8C while the optical confinement factor Γᵣ in the lateral direction was less than 1 and the optical confinement factor Γᵣ in the lateral direction was a function that decreases as the carrier density N increases. The reason why the optical confinement factor Γᵣ in the lateral direction is the above-described function is to take in the influence of a change in refractive index due to the carrier plasma effect. FIG. 13 is a graph presenting an example of the function. FIG. 14 is a graph presenting simulation results for the optical outputs.

As presented in FIG. 14, an optical pulse output is obtained at a timing at which the injection of the pulse current is stopped. As described above, in the simulation, results close to the actual measurement results presented in FIGS. 8A to 8C are obtained.

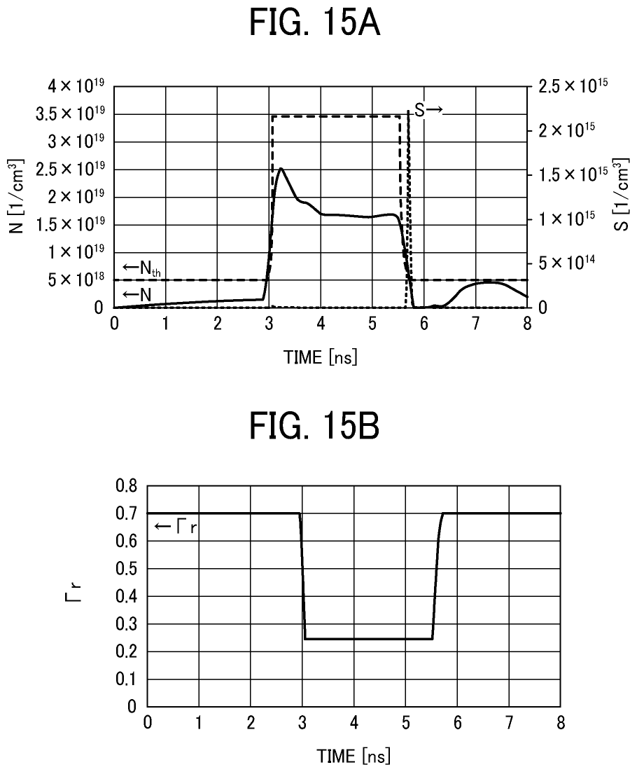

To analyze the results in detail, FIGS. 15A and 15B present simulation results of the carrier density N, the threshold carrier density Nₜₕ, the photon density S, and the optical confinement factor Γᵣ in the lateral direction under the condition of the pulse width being 2.5 ns. FIG. 15A presents simulation results of the carrier density N, the threshold carrier density Nₜₕ, and the photon density S. FIG. 15B presents a simulation result of the optical confinement factor Γᵣ in the lateral direction.

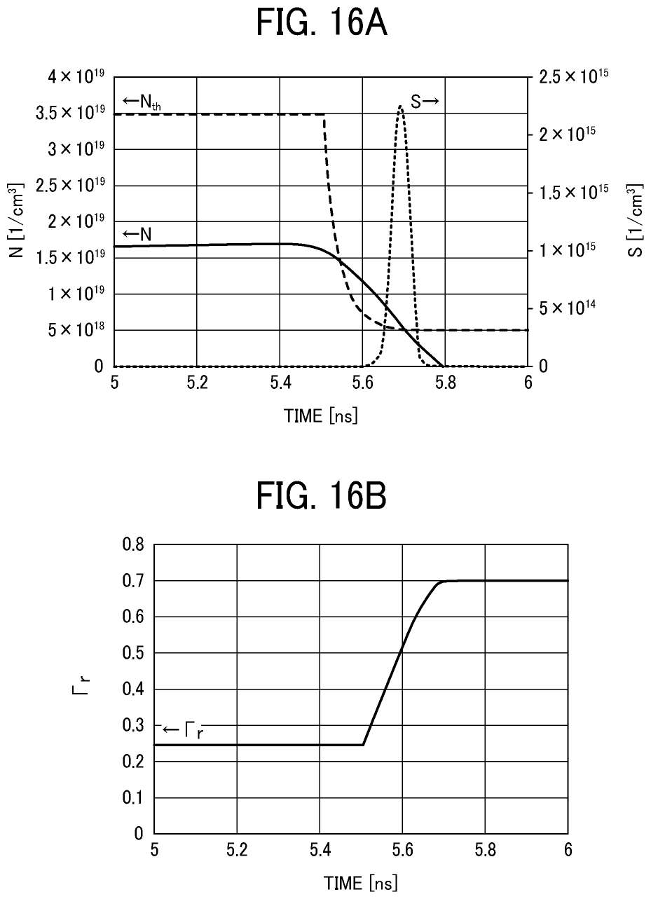

Since the optical confinement factor Γᵣ in the lateral direction is the function of the carrier density N, the optical confinement factor Γᵣ in the lateral direction decreases in a range from 3 ns to 5.5 ns in which the pulse current is injected. Within this range, the threshold carrier density Nₜₕ increases along with a decrease in the optical confinement factor Γᵣ in the lateral direction, and N<Nₜₕ is established. Hence induced emission is less likely to occur, and the photon density S does not increase. When the injection of the pulse current starts decreasing at the time point of about 5.5 ns, the optical confinement factor Γᵣ in the lateral direction increases again, and in the process, the photon density S appears in a pulse form. FIGS. 15A and 15B are graphs in which the time width in the range from 5 ns to 6 ns in FIGS. 16A and 16B is expanded.

When the injection of the pulse current starts decreasing at the time point of about 5.5 ns, the carrier density N starts decreasing. At the same time, the optical confinement factor Γᵣ in the lateral direction increases, and the threshold carrier density Nₜₕ decreases. Since the decrease in the threshold carrier density Nₜₕ is faster than the decrease in the carrier density N, there is a period in which N>Nₜₕ is established in the process of the decrease in the carrier density N. During this period, the photon density S first increases due to spontaneous emission, and when the photon density S increases by a certain degree, induced emission becomes dominant, and the photon density S rapidly increases. At the same time, the carrier density N rapidly decreases, and when N<Nₜₕ is established again, the photon density rapidly decreases.

As described above, the phenomenon in which the optical pulse is output when the injection of the pulse current is stopped as a trigger can be reproduced by the simulation.

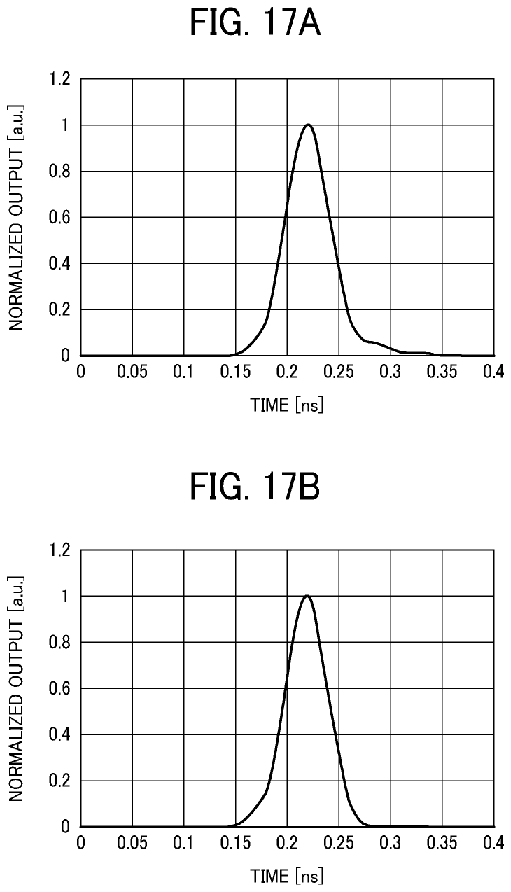

The rising time of the optical pulse decreases as the threshold carrier density Nₜₕ decreases faster than the carrier lifetime. That is, based on Equation (6), the rising time decreases as the increase in the lateral optical confinement factor Γᵣ is faster. The attenuation time of the optical pulse depends on the photon lifetime. FIGS. 17A and 17B are graphs presenting examples of an actual measurement result and a simulation result of optical pulses. FIG. 17A presents an actual measurement result. FIG. 17B presents a simulation result.

When the pulse width is defined as a time width of 1/e² or more of the peak value, the obtained optical pulse width is 86 ps in the actual measurement result in FIG. 17A, and is 81 ps in the simulation result in FIG. 17B. In this case, e is a natural logarithm. With this model, the width of the optical pulse is shorter than the pulse current to be injected, and can be decreased without being limited by the time width of the pulse current to be injected.

### FIRST EMBODIMENT

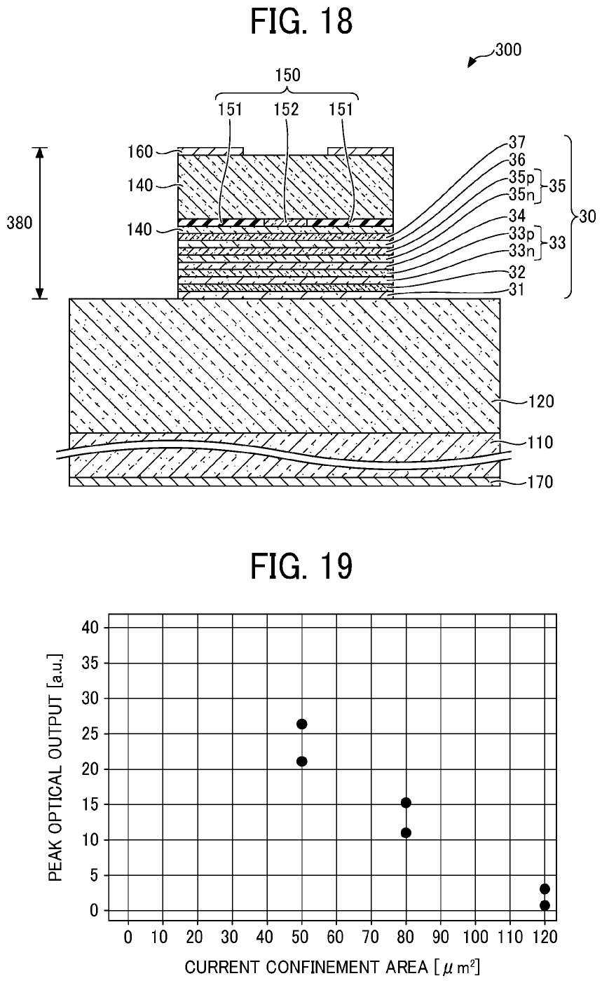

Next, the first embodiment will be described. The first embodiment relates to a front surface-emission type surface emitting laser. The first embodiment differs from the first reference example in the configurations of the resonator and the mesa. The first embodiment includes a multi-junction structure. FIG. 18 is a cross-sectional view of a surface emitting laser according to the first embodiment.

The surface emitting laser 300 according to the first embodiment is, for example, a vertical cavity surface emitting laser (VCSEL) using oxidation confinement. The surface emitting laser 300 includes an n-type GaAs substrate 110, an n-type distributed Bragg reflector (DBR) 120, a resonator 30, a p-type DBR 140, an oxidized confinement layer 150, an upper electrode 160, and a lower electrode 170.

In the present embodiment, light is emitted in a direction perpendicular to a surface of the n-type GaAs substrate 110. Hereinafter, the direction perpendicular to the surface of the n-type GaAs substrate 110 may be referred to as a vertical direction, and the direction parallel to the surface of the n-type GaAs substrate 110 may be referred to as a lateral direction or an in-plane direction.

The resonator 30 overlies the n-type DBR 120. The p-type DBR 140 overlies the resonator 30. The resonator 30 includes a spacer layer 31, an active layer 32, a tunnel junction 33, an active layer 34, a tunnel junction 35, an active layer 36, and a spacer layer 37. The spacer layer 31 overlies the n-type DBR 120. The active layer 32 overlies the spacer layer 31. The tunnel junction 33 overlies the active layer 32. The active layer 34 overlies the tunnel junction 33. The tunnel junction 35 overlies the active layer 34. The active layer 36 overlies the tunnel junction 35. The spacer layer 37 overlies the active layer 36. The p-type DBR 140 overlies the spacer layer 37.

The spacer layers 31 and 37 are, for example, Al_{0.2}Ga_{0.8}As layers. Each of the active layers 32, 34, and 36 has, for example, a multiple quantum well structure including multiple quantum well layers and barrier layers. The quantum well layers are, for example, are InGaAs layers, and the barrier layers are AlGaAs layers. For example, the emission wavelengths of the active layers 32, 34 and 36 are 940 nm. The surface emitting laser 300 is a surface emitting laser with an oscillation wavelength of 940 nanometer (nm) band.

The tunnel junction 33 has an n-type layer 33n and a p-type layer 33p. The tunnel junction 35 has an n-type layer 35n and a p-type layer 35p. The n-type layer 33n overlies the active layer 32, and the p-type layer 33p overlies the n-type layer 33n. The n-type layer 35n overlies the active layer 34, and the p-type layer 35p overlies the n-type layer 35n. For example, the n-type layers 33n and 35n are n⁺⁺AlGaAs layers having a thickness of 5 nm to 20 nm, and the p-type layers 33p and 35p are p⁺⁺AlGaAs layers having a thickness of 5 nm to 20 nm. For example, the n-type impurity of the n-type layers 33n and 35n has a concentration of 5×10¹⁸ cm⁻³, and the p-type impurity of the p-type layers 33p and 35p has a concentration of 5×10¹⁹ cm⁻³.

In the resonator 30, the active layers 32, 34, and 36 are provided at positions corresponding to antinodes of the standing wave of the oscillation light so as not to reduce the light emission efficiency. In the resonator 30, the tunnel junctions 33 and 35 are provided at positions corresponding to nodes of a standing wave in order to avoid light absorption. The positions of the active layers 32, 34, and 36 are not limited to the positions corresponding to the antinodes of the standing wave, but it is preferable that each of the active layers 32, 34, and 36 are provided between the antinode and the intermediate position between the antinode and the node of the standing wave of the oscillation light.

In the present embodiment, the p-type DBR 140 and the resonator 30 constitute the mesa 380. However, in the present embodiment in which a current confinement region is formed by oxidation confinement, at least the oxidized confinement layer 150 and a semiconductor layer located above the oxidized confinement layer 150 are formed in a mesa shape. When at least the active layer is formed to be included in the mesa, light generated in the active layer can be prevented from leaking in the lateral direction.

The other configurations are similar to those in the first reference example.

In the first embodiment, a continuous optical pulse train is less likely to be generated after the optical pulse output is generated. This is because the injection of the pulse current decreases when the optical pulse is generated, and the relaxation oscillation is less likely to be generated.

Moreover, tail light is less likely to be generated after the optical pulse output is generated. This is because the injection of the pulse current decreases after the optical pulse is generated, and the carrier density is less likely to increase.

Furthermore, since the optical pulse is output immediately after the injection of the pulse current is stopped, the timing at which the optical pulse is output can be desirably controlled.

Furthermore, the width of the optical pulse generated according to the first embodiment is smaller than the width of the injected pulse current.

Even when the current is increased, the pulse current width does not have to be decreased, and hence the pulse current width is less likely to be affected by parasitic inductance.

The first embodiment allows a reduction in variations in oscillation characteristics that occurs from multiple quantum well layers and achieve both a high pulse output and a short pulse width. For example, in a case where gain switching oscillation is simply applied to a surface emitting laser having a normal multi-junction structure, relaxation oscillation at the rise of input of a pulse current is used. This more likely causes the number of carriers in each well to vary because of variations in current injected into each well. The variations in the injected current is caused by, for example, a difference in current density due to a difference in distance from the oxidized confinement layer or a variation in electrical characteristics (CR characteristics) of the tunnel junction. The value and the temporal change of the number of carriers at the rising time after the current pulse is input differ for each well. As a result, the oscillation characteristics vary, the peak output decreases, and the pulse width increases. However, in the first embodiment, short pulse oscillation occurs not at the time of rising but after sufficient carriers are supplied to each well so that a stable state is obtained. This allows the surface emitting laser 300 to be less affected by transient variations in the number of carriers, and enables a reduction in variations in oscillation characteristics that occurs from multiple quantum well layers.

Multiple surface emitting lasers 300 according to the first embodiment may be arranged in parallel to form a surface emitting laser array, and optical pulses may be simultaneously output, thereby obtaining a larger optical peak output. The current injected into the surface emitting laser array is larger than the current injected into one surface emitting laser 300; however, since the width of the optical pulse output from the surface emitting laser 300 is smaller than the width of the injected pulse current, the optical pulse with a small width can be output.

The pulse width of the light output from the surface emitting laser 300 according to the first embodiment is not limited; however, the pulse width is, for example, 1 ns or less, preferably 500 ps or less, and more preferably 100 ps or less.

In the first embodiment, the thickness of the oxidized region 151 at a position 3 μm separated outward from the inner edge of the inner region 154, that is, at a position 3 μm separated outward from a tip end portion of the boundary between the non-oxidized region 152 and the oxidized region 151, is preferably twice or less the thickness of the non-oxidized region 152. For example, when the thickness of the non-oxidized region 152 is 31 nm, the thickness at the position 3 μm separated outward from the inner edge of the inner region 154 is preferably 62 nm or less, and may be 54 nm. When the distance (oxidation distance) from the side surface of the mesa 280 to the inner edge of the oxidized region 151 is in a range from 8 μm to 11 μm, the distance of 3 μm corresponds to 28% to 38% of the oxidation distance. When the thickness of the oxidized region 251 and the thickness of the non-oxidized region 252 were measured at the position 3 μm separated outward from the inner edge of the oxidized region 251 in actual measurement of the above-described second reference example, the thickness of the oxidized region 951 was 79 nm, and the thickness of the non-oxidized region 252 was 31 nm. The thickness of the oxidized region 951 was 2.55 times the thickness of the non-oxidized region 252. As a result of comparative evaluation of various elements having oxide confinement structures, the inventors have found that the optical confinement factor Γᵣ in the lateral direction decreases when the ratio is 2 or less, and short-pulse light with a high output and no tailing is likely to be obtained.

The area (current confinement area) of the non-oxidized region 152 in plan view is desirably 120 μm² or less. As a result of comparative evaluation of various elements of the non-oxidized region 152, the inventors have found that the phenomenon in which the optical pulse is output immediately after the injection of the pulse current is stopped is less likely to occur when the non-oxidized region 152 has an area exceeding 120 μm². Moreover, it was found that an optical pulse with a high peak output is likely to be obtained as the non-oxidized region 152 is smaller. FIG. 19 is a graph presenting measurement results of a peak optical output for a sample in which the area of a non-oxidized region is in a range from 50 μm² to 120 μm².

### SECOND EMBODIMENT

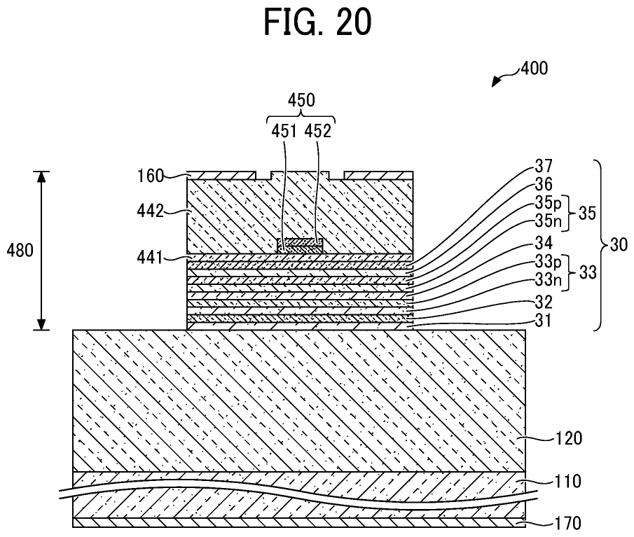

The second embodiment will be described. The second embodiment relates to a front surface-emission type surface emitting laser. FIG. 20 is a cross-sectional view of a surface emitting laser according to the second embodiment.

The surface emitting laser 400 according to the second embodiment is, for example, a VCSEL including a current confinement structure based on a buried tunnel junction (BTJ). The surface emitting laser 400 includes an n-type GaAs substrate 110, an n-type DBR 120, a resonator 30, a p-type DBR 441, a BTJ region 450, a p-type DBR 442, an upper electrode 160, and a lower electrode 170.

The p-type DBR 441 overlies the resonator 30. The p-type DBR 441 is, for example, a semiconducting multilayer reflector consisting of a plurality of p-type semiconductor films that are multilayered. The BTJ region 450 is on a portion of the p-type DBR 441. The BTJ region 450 includes a p-type layer 451 and an n-type layer 452. The p-type DBR 442 overlies the p-type DBR 441 and covers the BTJ region 450. The p-type DBR 442 is, for example, a semiconducting multilayer reflector consisting of multiple p-type semiconductor films that are multilayered. The p-type DBR 442, the p-type DBR 441, and the resonator 30 constitute a mesa 480. The BTJ region 450 is located at the center of the mesa 480 in the plane.

The p-type layer 451 overlies the p-type DBR 441, and the n-type layer 452 overlies the p-type layer 451. The p-type layer 451 contains a p-type impurity at a concentration higher than that of the p-type semiconductor film constituting the p-type DBR 441. The n-type layer 452 contains an n-type impurity at a concentration higher than that of the n-type semiconductor film constituting the p-type DBR 442. For example, the thickness of the p-type layer 451 is from 5 nm to 20 nm, and the thickness of the n-type layer 452 is from 5 nm to 20 nm. In plan view, a portion of the mesa 480 inside the contour of the BTJ region 450 is an example of a high refractive index region, and a portion of the mesa 480 outside the contour of the BTJ region 450 is an example of a low refractive index region.

The upper electrodes 160 are in contact with the upper surface of the p-type DBR 442. The lower electrode 170 is in contact with a lower surface of the n-type GaAs substrate 110. The pair of the upper electrode 160 and the lower electrode 170 is an example of an electrode pair.

In the second embodiment, a current does not flow between the p-type DBR 441 and the p-type DBR 442 because of a reverse bias. A current due to a buried tunnel junction flows between the p-type layer 451 and the n-type layer 452. Thus, the current path between the upper electrode 160 and the lower electrode 170 is confined at the center of the mesa 480 including the BTJ region 450. Moreover, since the BTJ region 450 forms a step and is covered with the p-type DBR 442, the refractive index in a plane of the mesa 480 is high at the center and is low in the periphery. Thus, an optical confinement effect in the lateral direction is generated in the surface emitting laser 400.

Thus, also according to the second embodiment, an optical pulse can be output by injecting pulse current similar to that in the first embodiment.

### THIRD EMBODIMENT

The third embodiment will be described.

As described above, the number of carriers accumulated in the active layer is preferably increased to increase the obtained short pulse output. Further, N>Nₜₕ is to be established in as short a time as possible after the current injection is stopped.

When the current injection is stopped, the carrier density decreases at the central portion in the vicinity of the active layer in the current confinement structure due to diffusion, spontaneous emission, and non-radiative recombination of carriers, and the transverse mode distribution whose spread is due to the plasma effect becomes a distribution in the central portion of the device. As a result. N>Nₜₕ is established, and short pulse oscillation occurs. During the oscillation of short pulses, the carrier loss is to be reduced to increase pulse output power.

In the above example, the current injection for obtaining an output serves to reduce oscillation of light due to refractive index changes resulting from the plasma effect, accumulated carriers partly disappear until the short pulse oscillation occurs. If the refractive index can be changed by means other than the plasma effect irrespective of the amount of currents to be injected injection and the amount of accumulated carriers, the accumulated carriers can be effectively converted into short-pulse output to be extracted, and short-pulse operation with higher efficiency and higher output can be performed.

As a means for externally modulating the refractive index, an electric field effect of a multi-quantum well structure is effective. In the multiple-quantum well structure, a change in the refractive index, that is, a decrease in refractive index can be obtained by applying an electric field in a direction perpendicular to the well surface.

A change in refractive index due to an electric field in a quantum-well structure is reported in, for example, NPL 1, NPL 2, NPL 3, and NPL 4. In Non-Patent Document 1, it is theoretically reported that a value of (Δn/n)/E=3×10⁻⁸ cm/V is obtained in a quantum-well structure composed of InGaAsP and InP having 30 nm thicknesses. For example, when an electric field of 100 kV/cm is applied (bias of 0.3 V with respect to the quantum-well of 30 nm), Δn/n is 3×10⁻³ (Δn/n=3×10⁻³), that is, Δn is approximately equal to −9×10⁻³ (Δn≈−9× 10⁻³).

In NPL 2 and NPL 3, (Δn/n)/E was actually observed to be 4×10⁻⁷ cm/V at room temperature in a multi-quantum-well structure composed of GaAs having a thickness of 10 nm and AlAs having a thickness of 30 nm. This means that Δn is approximately equal to −4×10⁻² (Δn≈−4×10⁻²) when an electric field of 100 kV/cm is applied, and a value greater than the theoretical value in NPL 1 is observed. NPL 3 indicates that a red shift of interband transition energy and a change in refractive index due to the quantum-confined Stark effect caused by application of an electric field. In NPL 4, a value of Δn approximately equal to −3× 10⁻² (Δn≈−3×10⁻²) is reported as an experimental result.

As described above, the electric field effect of the multiple quantum-well structure enables a refractive index change equal to or greater than that of the plasma effect of Δn approximately equal to −1×10⁻² order in a realistically applied electric field of 100 kV/cm. This enables further improvement of the control of the short-pulse operation and the pulse output power.

When an electric field is applied to such a multi-quantum well structure arranged near the resonator, the refractive index of quantum well of the multi-quantum well structure decreases and acts in a direction to cancel the effective refractive index difference Δn0 obtained by the oxidized confinement as presented in FIGS. 10A and 10B. In other words, another means, in addition to the plasma effect, for changing the effective refractive index difference Δn is available. Further, controlling the effective refractive index difference Δn by using the electric field applied to the multiple-quantum well enables control of the timing of oscillation of a short pulse which is laser oscillation.

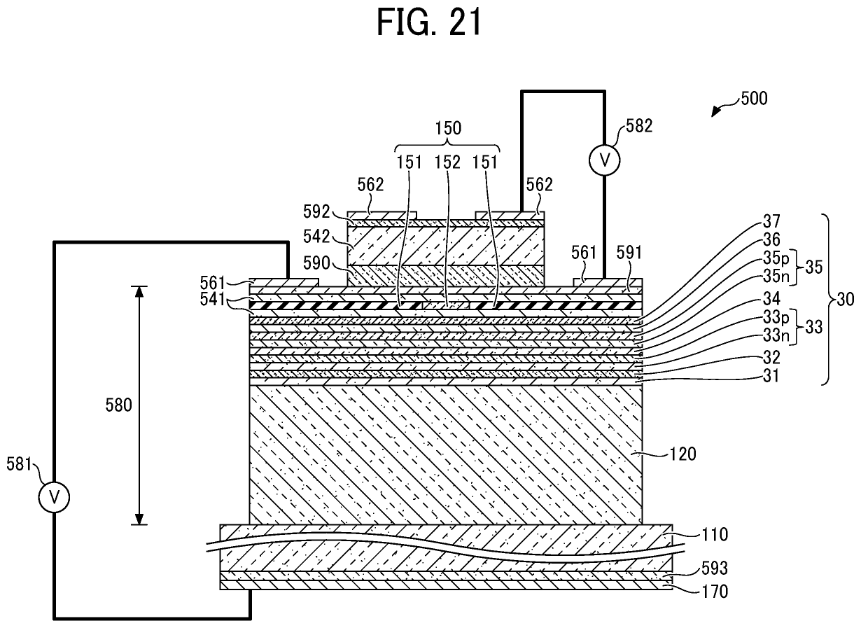

In the third embodiment, the field effect of the multiple quantum well structure is utilized. The third embodiment relates to a front surface-emission type surface emitting laser. FIG. 21 is a cross-sectional view of a surface emitting laser according to the third embodiment.

Similarly to the first embodiment, the surface emitting laser 500 according to the third embodiment is, for example, a VCSEL using oxidation confinement. The surface emitting laser 500 includes an n-type GaAs substrate 110, an n-type DBR 120 as a lower reflector, a resonator 30, a first p-type DBR 541, a second p-type DBR 542, an oxidized confinement layer 150, a multi-quantum well structure 590, a first upper electrode 561, a second upper electrode 562, and a lower electrode 170. The surface emitting laser 500 further includes a first contact layer 591, a second contact layer 592, and a third contact layer 593.

The first p-type DBR 541 overlies the resonator 30. The first p-type DBR 541 includes an oxidized confinement layer 150. The first contact layer 591 overlies the first p-type DBR 541. The multi-quantum well structure 590 overlies the contact layer 591. The second p-type DBR 542 is on the multi-quantum well structure 590. The second contact layer 592 is on the second p-type DBR 542. The third contact layer 593 is located between the n-type GaAs substrate 110 and the lower electrode 170. The n-type DBR 120, the resonator 30, the first p-type DBR 541, and the first contact layer 591 constitute a cylindrical mesa post 580. The first p-type DBR 541 is an example of a first upper reflector, and the second p-type DBR 542 is an example of a second upper reflector.

For example, the n-type DBR 120 includes 40 pairs of n-type Al_{0.1}Ga_{0.9}As films and Al_{0.9}Ga_{0.1}As films. For example, the first p-type DBR 541 is composed of four pairs of p-type Al_{0.1}Ga_{0.9}As film and Al_{0.9}Ga_{0.1}As film. For example, the second p-type DBR 542 is composed of 16 pairs of p-type Al_{0.1}Ga_{0.9}As film and Al_{0.9}Ga_{0.1}As film.

The multi-quantum well structure 590 includes multiple semi-conductor layers including, for example, 20 pairs of InGaAs film and AlGaAs film. The first contact layer 591 and the second contact layer 592 are, for example, p-type GaAs layers. The third contact layer 593 is, for example, an n-type GaAs layer.

The first embodiment and the second embodiment may include the second contact layer 592 and the third contact layer 593.

In the multi-quantum well structure 590 for refractive index modulation, the energy between bands is set to be approximately equal to the photon energy of the oscillation wavelength with an electric field applied. When an electric field is applied, the effective band gap energy decreases due to the quantum confined Stark effect. With such a reduction in the band gap energy, red-shifting the wavelength of the absorption edge allows light having a longer wavelength to be absorbed. When the effective band gap energy at the time of applying the electric field is larger than the photon energy, the absorption loss can be reduced. When the effective band gap energy is smaller than the photon energy, the oscillation can be further reduced by the absorption loss. The oxidized confinement layer 150 in the first p-type DBR 541 is formed by forming a p-type AlAs selectively oxidized layer having a thickness of 20 nm in the first p-type DBR 541 before forming the cylindrical mesa post 580 and then oxidizing the p-type AlAs selectively oxidized layer in heated water vapor. The multi-quantum well structure 590, the second p-type DBR 542, and the second contact layer 592 each have a cylindrical shape. The planar shape of the mesa post 580 is not limited to a circle, and may be any shape such as a square, a rectangle, or a hexagon.

The planar shape of the first upper electrode 561 is annular, and the first upper electrode 561 is located on the surface of the first contact layer 591. The planar shape of the second upper electrode 562 is annular, and the second upper electrode 562 is located on the surface of the second contact layer 592. The lower electrode 170 is on the back surface of the third contact layer 593.

A first power supply device 581 is connected to a first electrode pair including the first upper electrode 561 and the lower electrode 170. The first power supply device 581 injects current into the active layers 32, 34 and 36 in the resonator 30. A second power supply device 582 is connected to a second electrode pair including a second upper electrode 562 and a first upper electrode 561. The second power supply device 582 applies an electric field to the multiple-quantum well structure 590 for refractive index modulation. Although the second upper reflector may be undoped, by using a second p-type DBR 542 as the second upper reflector, the electric resistance of the second upper reflector is reduced, and the voltage applied from the second power supply device 582 to the multi-quantum well structure 590 can be reduced.

Next, the operation principle of the surface emitting laser 500 will be described in detail. First, the second power supply device 582 applies an electric field to the multi-quantum well structure 590 in advance. When an electric field is applied, the effective refractive index of the central portion of the device, i.e., the central portion of the surface emitting laser 500 decreases with respect to the effective index difference Δn0 obtained from the oxidized confinement layer 150 during application of no electric field. With an electric field applied to the multi-quantum well structure 590, the effective refractive index difference Δn is smaller than the effective refractive index difference Δn0.

Next, the first power supply device 581 starts injecting a current into the active layers 32, 34, and 36 in the resonator 30. In other words, at least part of the current injection period is included in at least part of the electric-field application period. At this time, the effective refractive index difference Δn further decreases due to the plasma effect. Such two actions described above reduce the transverse mode distribution in the central portion of the device, and oscillation is suppressed, and causes carriers to be accumulated in the active layers 32, 34, and 36 whose oscillation is reduced.

When the electric field effects of the multi-quantum well structure 590 is used in combination, the effective refractive-index difference Δn0 obtained from the oxidized confinement layer 150 is set to be slightly larger. Then, the change in refractive index due to the electric field effect and the plasma effect of the carriers in the multi-quantum well structure 590 is combined to establish the relation between the threshold carrier density Nₜₕ and the carrier density N as presented in FIG. 15A. In other words, the oscillation is reduced by both the plasma effect and the electric field effect.

Next, the second power supply device 582 stops the application of the electric field to the multiple quantum well structure 590 for refractive index modulation. As a result, the interband transition energy of the multiple quantum well structure 590 is increased. In other words, the red-shift due to the quantum-confined Stark effect is eliminated, to cause transparency to the oscillation wavelength while increasing the effective refractive index difference Δn. With an increase in the effective refractive index difference Δn, the transverse mode distribution in the central portion of the device is increased to reduce the oscillation threshold and immediately cause short-pulse oscillation. At this time, if the first power supply device 581 also stops injecting currents into the active layers 32, 34, and 36 in the resonator 30 at the same time of stopping the second power supply device 582, a larger change in refractive index can be obtained.

When the oscillation is reduced by the plasma effect alone, the effective refractive index difference Δn which has been reduced by the plasma effect after the stop of the current injection into the active layer 36 is recovered to allow the oscillation as described below. In other words, the carriers accumulated in the active layers 32, 34, and 36 are recovered by diffusion from the current injection path or reduction by recombination process in the active region. However, carriers that do not contribute to the oscillation during that time are partly lost.

However, in the third embodiment, since the refractive index change is immediately caused by the control of the electric field applied from the second power supply device 582 to the multi-quantum well structure 590, the amount of carriers that do not contribute to oscillation can be significantly reduced. This enables the peak output especially at the start of oscillation to be greatly improved. Notably, the effective refractive index difference Δn0 due to the oxidized confinement layer 150 can be changed by changing the thicknesses of the oxidized confinement layer 150, and can be increased by thickening the oxidized confinement layer 150.

The effective refractive index difference Δn0 obtained from the oxidized confinement layer 150 is set so that oscillation starts when the application of an electric field to the multi-quantum well structure 590 is stopped. In other words, oscillation is not performed during the electric-field application period, but is performed during the electric-field decrease period. The first embodiment with such a configuration combines the plasma effect with the electric field effect. This configuration enables reduction of the oscillation more significantly than the case of using the plasma effect alone. Thus, the first embodiment enables more carriers to be accumulated in the active layer and a higher peak output power of the short-pulse oscillation.

As described above, as the amount of change in the refractive index due to the electric field effect increases, a larger effect of reducing oscillation can be obtained, and the number of accumulated carriers can be increased. Further, the effective refractive index difference Δn0 obtained from the oxidized confinement layer 150 is increased with the oscillation reduction effect maintained to enable an increase in the amount of change in the oscillation threshold value when the application of the electric field is stopped. This enables a reduction in the number of invalid carriers to disappear before the start of oscillation of the short pulse, and thus achieve a higher output power.

Such effects can be obtained by placing the multi-quantum well structure 590 at any position in the path of the laser light to obtain the refractive index change due to the electric field effect. Further, the multi-quantum well structure 590 can be closer to the active layers 32, 34, and 36 or the amount of change in the refractive index due to the electric field effect on the multi-quantum well structure 590 can be increased by increasing the number of quantum wells.

Furthermore, since the optical pulse is output immediately after the injection of the pulse current into the multi-quantum well structure 590 is stopped in the third embodiment, the timing at which the optical pulse is output can be desirably controlled.

In addition, since the number of accumulated carriers can be increased and invalid carriers not contributing to oscillation can be reduced, a higher output power can be obtained.

In the third embodiment, a continuous optical pulse train is less likely to be generated after the optical pulse output is generated. This is because the injection of the pulse current decreases when the optical pulse is generated, and the relaxation oscillation is less likely to be generated.

Moreover, tail light is less likely to be generated after the optical pulse output is generated. This is because the injection of the pulse current decreases after the optical pulse is generated, and the carrier density is less likely to increase.

Furthermore, the width of the optical pulse generated according to the third embodiment is smaller than the width of the injected pulse current.

Even when the current is increased, the pulse current width does not have to be decreased, and hence the pulse current width is less likely to be affected by parasitic inductance. Similarly to the first embodiment, multiple surface emitting lasers 500 according to the third embodiment may be arranged in parallel to form a surface emitting laser array, and optical pulses may be simultaneously output, thereby obtaining a larger optical peak output. The current injected into the surface emitting laser array is larger than the current injected into one surface emitting laser 500; however, since the width of the optical pulse output from the surface emitting laser 500 is smaller than the width of the injected pulse current, the optical pulse with a small width can be output.

Similarly to the first embodiment, the pulse width of the light output from the surface emitting laser 500 according to the third embodiment is not limited; however, the pulse width is, for example, 1 ns or less, preferably 500 ps or less, and more preferably 100 ps or less.

Similarly to the first embodiment, in the third embodiment, the thickness of the oxidized region 151 at a position 3 μm separated outward from the inner edge of the inner region 154, that is, at a position 3 μm separated outward from a tip end portion of the boundary between the non-oxidized region 152 and the oxidized region 151, is preferably twice or less the thickness of the non-oxidized region 152.

Similarly to the first embodiment, also in the third embodiment, it is desirable that the area (current confinement area) of the non-oxidized region 152 in a plan view is 120 μm² or less.

### FOURTH EMBODIMENT

The third embodiment will be described. The fourth embodiment relates to a front surface-emission type surface emitting laser. The fourth embodiment differs from the third embodiment mainly in the configurations of the second upper electrode.

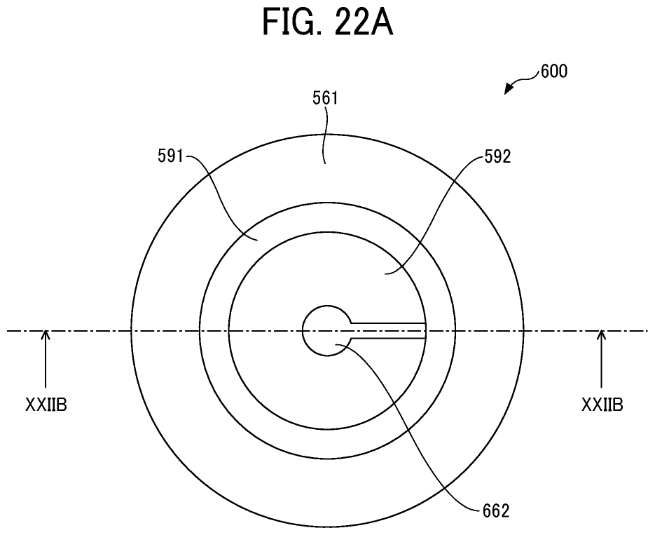

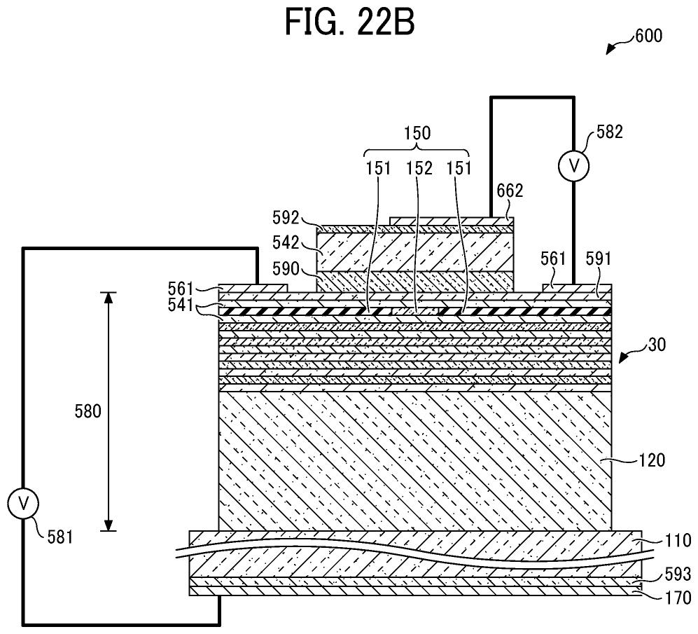

FIG. 22A is a top view of a surface emitting laser according to the fourth embodiment. FIG. 22B is a cross-sectional view of the surface emitting laser according to the fourth embodiment. FIG. 22B is a cross-sectional view of the surface emitting laser taken along line XXIIB-XXIIB in FIG. 22A.

The surface emitting laser 600 according to the fourth embodiment includes a second upper electrode 662 instead of the second upper electrode 562. The second upper electrode 662 is a transparent electrode. The second upper electrode 662 has a substantially circular planar shape and, as illustrated in FIG. 22A, is located at the central portion of the cylindrical first p-type DBR 541 in plan view. As illustrated in FIG. FIG. 22B, the second upper electrode 662 is led out from the central portion and is connected to the second power supply device 582 at an outer portion that does not inhibit transmission of a laser beam.

Other configurations are the same as those of the third embodiment.

Since the second upper electrode 662 is a transparent electrode, the second upper electrode 662 does not prevent transmission of laser light. According to the fourth embodiment, an electric field can be applied in a concentrated manner to the central portion of the multiple quantum well structure 590 in plan view. This enables a selective reduction in the effective refractive index in the central portion of the device.

Such a reduction in the effective refractive index difference in the central portion further enables a reduction in the intensity of the transverse mode distribution in the central portion of the device and thus achieves an effective reduction in the effective refractive index difference Δn.

As described above, the fourth embodiment exhibits the same effects as the third embodiment. According to the fourth embodiment, since the second upper electrode 662 is provided in the central portion of the element in plan view, the amount of change in the refractive index can be increased. Thus, the fourth embodiment achieves a higher output power laser beam.

An undoped second upper reflector may be used instead of the second p-type DBR 542, and the second contact layer 592 may be omitted. This prevents or reduces the electric field from being spread out in the lateral direction and further facilitates the selectivity of the operation. For example, the second upper reflector may be formed using a dielectric such as SiN or SiO₂.

### FIFTH EMBODIMENT

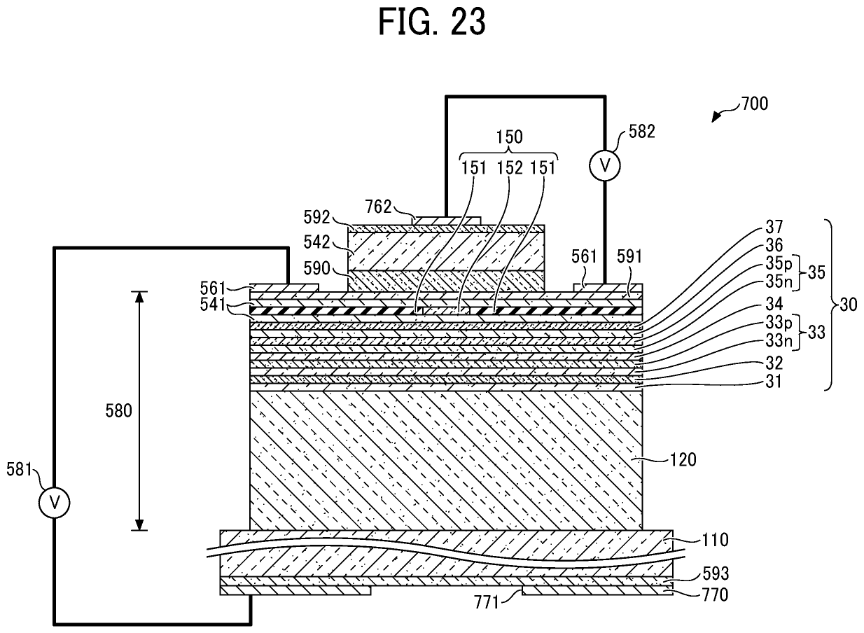

The following describes the fifth embodiment. The fifth embodiment relates to a back surface-emission type surface emitting laser. The fifth embodiment differs from the third embodiment mainly in the configurations of the lower electrode and the second upper electrode. FIG. 23 is a cross-sectional view of a surface emitting laser 900 according to the fifth embodiment.

In the surface emitting laser 700 according to the fifth embodiment, the number of pairs of upper multilayer film reflectors composed of the first p-type DBR 541 and the second p-type DBR 542 is 40 in total, and the number of pairs of lower multilayer film reflectors composed of the n-type DBR 120 is 20.

The surface emitting laser 700 includes a lower electrode 770 instead of the lower electrode 170. An opening 771 is formed in the lower electrode 770. The opening 771 is formed so as to overlap the non-oxidized region 152 in a plan view.

The surface emitting laser 700 includes a second upper electrode 762 instead of the second upper electrode 562. The second upper electrode 762 is located at the central portion of the cylindrical first p-type DBR 541 in plan view.

Other configurations are the same as those of the third embodiment.

In the fifth embodiment, optical output is emitted to the n-type GaAs substrate 110 (i.e., to the back surface).

Since the opening 771 is formed in the lower electrode 770, optical output is taken out without being obstructed by the lower electrode 770.

In addition, since the second upper electrodes 762 are located at the central portion of the cylindrical first p-type DBR 541 in a plan view, an electric field can be intensively applied to the central portion of the multi-quantum well structure 590 in a plan view. This enables a selective reduction in the effective refractive index in the central portion of the device in a similar manner to the fourth embodiment.

Such a reduction in the effective refractive index difference in the central portion further enables a reduction in the intensity of the transverse mode distribution in the central portion of the device and thus achieves an effective reduction in the effective refractive index difference Δn.

The fifth embodiment also attains effects similar to those of the third embodiment.

An undoped second upper reflector may be used instead of the second p-type DBR 542, and the second contact layer 592 may be omitted. This prevents or reduces the electric field from being spread out in the lateral direction and further facilitates the selectivity of the operation. For example, the second upper reflector may be formed using a dielectric such as SiN or SiO₂.

### SIXTH EMBODIMENT

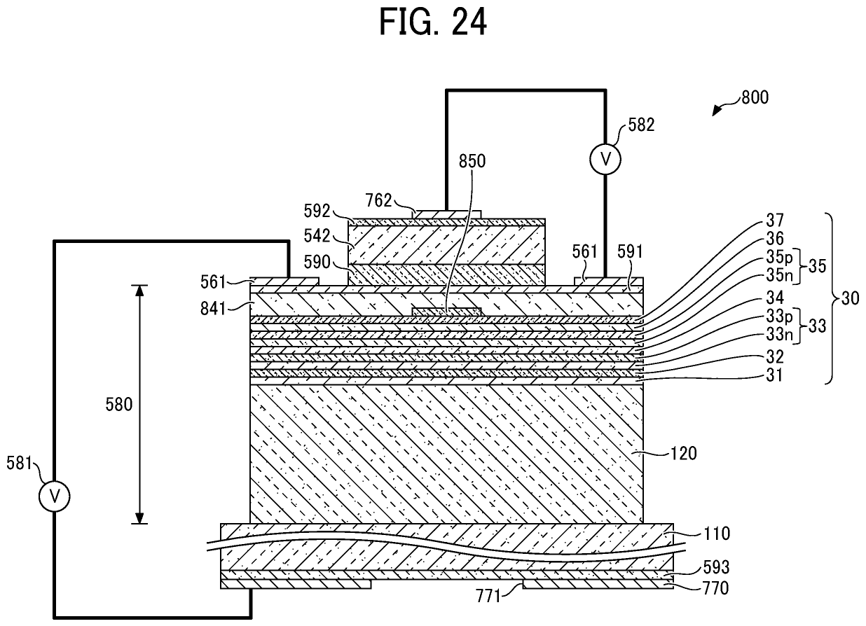

The sixth embodiment will be described. The sixth embodiment relates to a back surface-emission type surface emitting laser. The sixth embodiment differs from the fifth embodiment mainly in the configuration of the current confinement structure. FIG. 24 is a cross-sectional view of a surface emitting laser according to the sixth embodiment.

The surface emitting laser 800 according to the sixth embodiment is, for example, a VCSEL provided with a current confinement structure incorporating a BTJ. The surface emitting laser 800 has a BTJ region 850 instead of the oxidized confinement layer 150.

The BTJ region 850 is configured as follows. During the formation of the first p-type DBR 841, a p⁺⁺GaAs layer doped with p-type impurity higher in concentration than that of the first p-type DBR 841 and an n⁺⁺GaAs layer doped with n-type impurity higher in concentration than that of the n-type DBR 120 are grown. After the growth of that layers is once stopped, the two layers except for the central portion of the device are eliminated by selectively wet etching, so as to form the BTJ region 850. After the BTJ region 850 is formed, the remainder of the first p-type DBR 841 is grown again thereon.

The other configurations are similar to those in the fifth embodiment.

When a forward bias is applied to the first electrode pair composed of the lower electrode 770 and the first upper electrode 561, a reverse bias is applied to p⁺⁺GaAs layer and the n⁺⁺GaAs layer in the BTJ region 850. As a result, electrons band-to-band tunnels from p⁺⁺GaAs layer to the n⁺⁺GaAs layer, generating positive holes in p⁺⁺GaAs layer. With the holes, the electrons are injected to the active layers 32, 34, and 36 in the resonator 30.

The BTJ region 850 has a small refractive index difference due to the difference in the Al composition of the AlGaAs material in the lateral direction. Weak lateral optical confinement is formed based on such a refractive index difference. The lateral optical confinement has a degree that changes the effective refractive index difference Δn with a change in refractive index due to a plasma effect of carriers and an electric-field effect of the multiple-quantum well and enables oscillation of a short pulse.

The sixth embodiment also attains effects similar to those of the fifth embodiment.

### SEVENTH EMBODIMENT

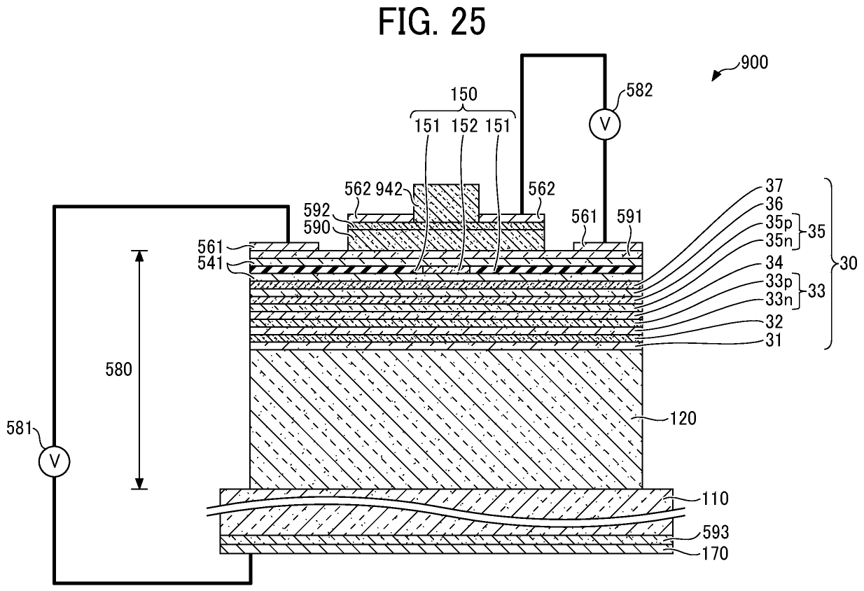

Next, a seventh embodiment will be described. The seventh embodiment relates to a front surface-emission type surface emitting laser. The seventh embodiment differs from the third embodiment mainly in the configurations of the second upper reflector. FIG. 25 is a cross-sectional view of a surface emitting laser according to the seventh embodiment.

The surface emitting laser 900 according to the seventh embodiment has a second p-type DBR 542 instead of the second p-type DBR 942. The second contact layer 592 overlies the multi-quantum well structure 590, and the second p-type DBR 942 overlies the second contact layer 592. The second p-type DBR 942 is located inside the second upper electrodes 562 in plan view.

The other structures are the same as those of the third embodiment.

In the seventh embodiment, the multi-quantum well structure 590 without passing through the second p-type DBR 942. This seventh embodiment allows more strengthened electric field of the multiple-quantum well structure 590 than that of the third embodiment. Thus, the seventh embodiment enables a larger amount of change in refractive index due to the electric field effects.

The seventh embodiment achieves a higher output power laser beam.

An undoped second upper reflector may be used instead of the second p-type DBR 942, and the second contact layer 592 may be omitted. This prevents or reduces the electric field from being spread out in the lateral direction and further facilitates the selectivity of the operation. For example, the second upper reflector may be formed using a dielectric such as SiN or SiO₂.

### EIGHTH EMBODIMENT

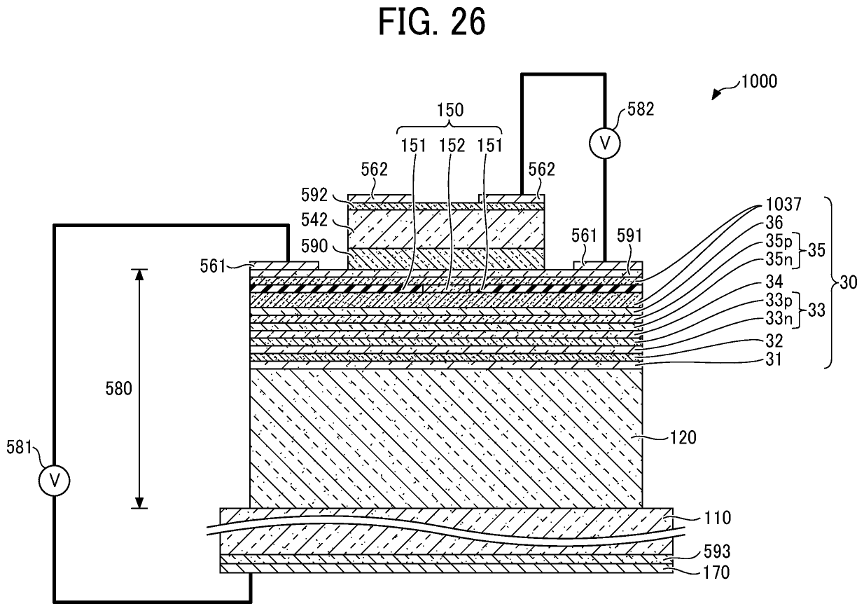

The eighth embodiment will be described. The eighth embodiment relates to a front surface-emission type surface emitting laser. The eighth embodiment differs from the third embodiment mainly in the configurations of the first upper reflector and the spacer layer. FIG. 26 is a cross-sectional view of a surface emitting laser according to the eighth embodiment.

The surface-emitting laser 1000 according to the eighth embodiment includes a spacer layer 1037 instead of the spacer layer 37 and the first p-type DBR 541. The spacer layer 1037 is thicker than the spacer layer 37, and the spacer layer 1037 includes an oxidized confinement layer 150.

Other configurations are the same as those of the third embodiment.

The eighth embodiment also attains effects similar to those of the third embodiment.

In the third to eighth embodiments, a multi-quantum well structure 590 for obtaining the electric field effects is between the active layer 32, 34, and 36 and the second p-type DBR 542 or 942. However, no limitation is intended thereby. Such effects can be obtained by placing the multi-quantum well structure 590 at any position in the path of the laser light to obtain the refractive index change due to the electric field effect.

### NINTH EMBODIMENT

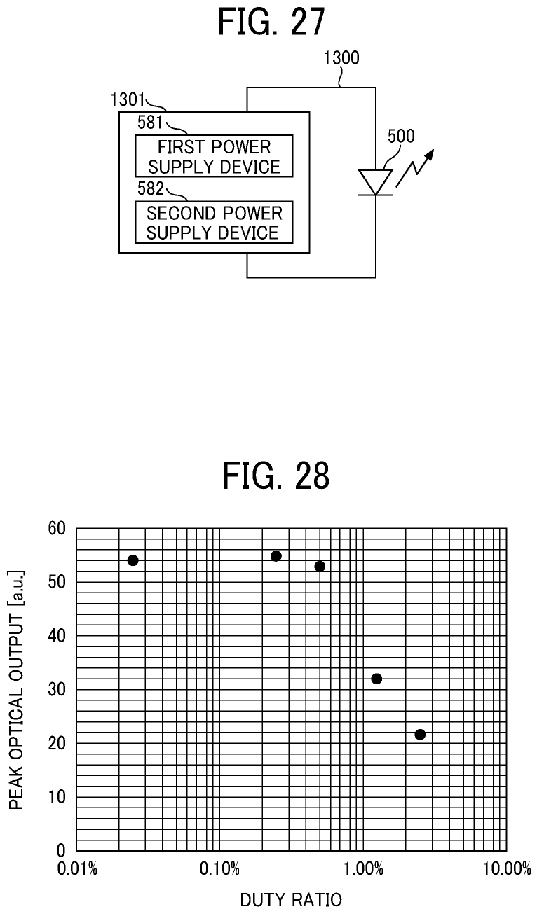

Next, the ninth embodiment will be described. The ninth embodiment relates to a laser device. FIG. 27 is a diagram of a laser device 300 according to the ninth embodiment.

The laser device 1300 according to the ninth embodiment includes the surface emitting laser 500 according to the third embodiment, and a power supply device 1301. The power supply device 1301 includes a first power supply device 581 and a second power supply device 582. The first power supply device 581 is connected to the first upper electrode 561 and the lower electrode 170. The second power supply device 582 is connected to the first upper electrode 561 and the second upper electrode 562. The first power supply device 581 injects a current into the surface emitting laser 500, and the second power supply device 582 applies an electric field to the surface emitting laser 500.

The duty ratio of the injection of current from the first power supply device 581 is preferably 0.5% or less. That is, it is desirable that the current injection period and the current decrease period are repeated a plurality of times, and the ratio of the current injection period to the current decrease period is 0.5% or less. The duty ratio is a ratio of a period in which a current pulse is injected in a unit period. When t [s] denotes a pulse current width and f [Hz] denotes a repetition frequency of pulse current, the duty ratio corresponds to f×t (%). FIG. 28 is a graph presenting the relationship between the duty ratio and the peak output of optical pulses when the pulse current width is 2.5 ns.

As presented in FIG. 28, when the duty ratio is more than 0.5%, the optical peak output tends to decrease. Conceivable reasons for this are the following models. First, when the duty ratio is increased, the amount of heat generated in the current confinement region (non-oxidized region 152) by the injected pulse current increases. Thus, the temperature of the center portion where the current is concentrated rises with respect to the peripheral portion of the current confinement region, and a temperature difference is generated. Consequently, the refractive index of the center portion of the current confinement region increases by a thermal lens effect, and the optical confinement factor in the lateral direction increases. As the optical confinement factor in the lateral direction increases due to the thermal lens effect, the influence of a change in refractive index due to the carrier plasma effect generated by an increase or a decrease in pulse current decreases. Thus, the phenomenon in which the optical pulse is output immediately after the injection of the pulse current is stopped is less likely to occur. In contrast, when the duty ratio is 0.5% or less, the influence of the change in refractive index due to the thermal lens effect is sufficiently small, and the change in refractive index derived from the confinement structure is dominant, and thus the peak output is considered to be substantially constant and not changed.

In one example, instead of the surface emitting laser 500 according to the third embodiment, the surface emitting laser according to the second embodiment to the sixth embodiment may be used.

### TENTH EMBODIMENT

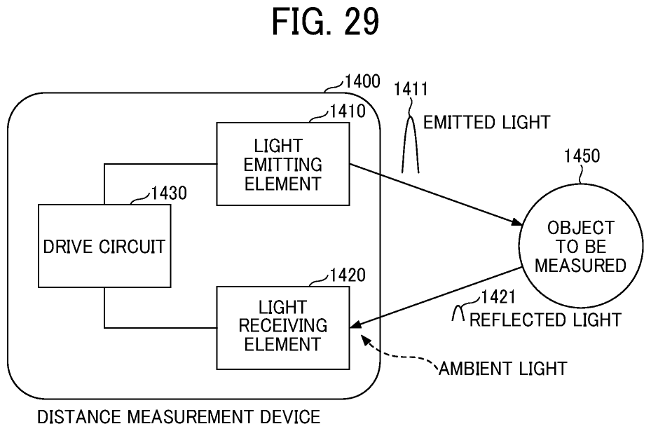

Next, the tenth embodiment will be described. The tenth embodiment relates to a distance measurement device. FIG. 29 illustrates a distance measurement device 1400 according to the tenth embodiment. The distance measurement device 1400 is an example of a detection device.

The distance measurement device 1400 according to the fourth embodiment is a distance measurement device based on a time of flight (TOF) method. The distance measurement device 1400 includes a light emitting element 1410, a light receiving element 1420, and a drive circuit 1430. The light emitting element 1410 emits an emission beam (irradiation light 1411) to a distance measurement object (an object to be measured) 1450. The light receiving element 1420 receives reflected light 1421 from the object 1450. The drive circuit 1430 drives the light emitting element 1410 and detects the difference in time between the emission timing of the emission beam and the reception timing of the reflected light 1421 by the light receiving element 1420 to measure the distance of reciprocation to and from the object 1450.

The light emitting element 1410 includes the surface emitting laser 100 according to the first embodiment to the eight embodiment. The repetition frequency of pulses is, for example, in a range from several kilohertz to several tens of megahertz.

The light receiving element 1420 is, for example, a photodiode (PD), an avalanche photodiode (APD), or a single photon avalanche diode (SPAD). The light receiving element 1420 may include a plurality of light receiving elements arranged in an array. The light receiving element 1420 is an example of a detector.

In the distance measurement by the TOF method, it is desirable to separate a signal from a distance measurement object and noise from each other.

When a farther distance measurement object is measured or when a distance measurement object with a lower reflectivity is measured, it is desirable to obtain a signal from the object using a light receiving element with a higher sensitivity. However, when a light receiving element with a higher sensitivity is used, the possibility of erroneously detecting background light noise or shot noise increases. To separate the signal and the noise from each other, the threshold value of the light receiving signal may be increased; however, it may be difficult to receive the signal light from the distance measurement object unless the peak output of the emission beam is increased by the amount by which the threshold value of the light receiving signal is increased. However, the output of the emission beam is limited by the safety standards for lasers.

The surface emitting laser according to the first embodiment to the sixth embodiment can output optical pulses having a pulse width of about 100 ps. This is about 1/10 compared to the value ns of the optical pulse width output from the surface emitting laser of the related art. According to the distance measurement device 1400 according to the tenth embodiment, since the peak output allowable under the safety standard increases as the pulse width of the optical pulse decreases, both an increase in precision and an increase in distance can be attained while eye-safe is satisfied.

### ELEVENTH EMBODIMENT

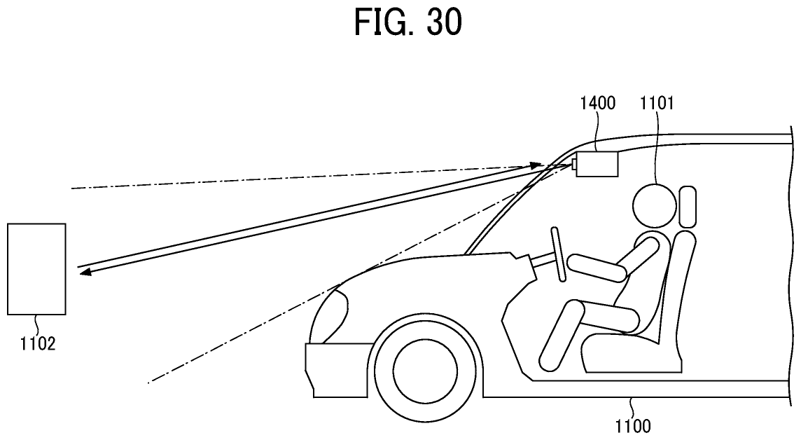

The eleventh embodiment will be described. The eleventh embodiment relates to a mobile object. FIG. 30 illustrates an automobile 1100 as an example of a mobile object according to the eleventh embodiment. The distance measurement device 1400 described in the tenth embodiment is provided at an upper portion of a front surface of the automobile 1100 (for example, an upper portion of a windshield) as an example of a mobile object according to the eleventh embodiment. The distance measurement device 1400 measures the distance to an object 1102 around the automobile 1100. The measurement result of the distance measurement device 1400 is input to a controller included in the automobile 1100, and the controller controls the operation of the mobile object based on the measurement result. Alternatively, the controller may provide warning indication on a display provided in the automobile 1100 to a driver 1101 of the automobile 1100 based on the measurement result of the distance measurement device 1400.

As described above, in the eleventh embodiment, since the distance measurement device 1400 is provided in the automobile 1100, the position of the object 1102 in the periphery of the automobile 1100 can be recognized with high precision. The installation position of the distance measurement device 1400 is not limited to the upper and front portion of the automobile 1100, and may be installed at a side surface or a rear portion of the automobile 1100. In this embodiment, the distance measurement device 1400 is provided in the automobile 1100; however, the distance measurement device 1400 may be provided in an aircraft or a ship. In one example, the distance measurement device 400 may be provided in a mobile object that moves autonomously without a driver, such as a drone or a robot.

Although the desirable embodiments and so forth have been described in detail, the present disclosure is not limited to the above-described embodiments and so forth, and various modifications and substitutions can be made without departing from the scope and spirit of the present disclosure as set forth in the claims.

According to Aspect 1, a surface emitting laser includes multiple active layers; a resonator including a tunnel junction between the multiple active layers; multiple reflectors sandwiching the resonator between the multiple reflectors; and an electrode pair connected to a power supply device through which a current is injected into the multiple active layers. The surface emitting laser does not oscillate a laser beam during a current injection period in which the power supply device injects the current into the multiple active layers through the electrode pair; and oscillates the laser beam during a current decrease period after the current injection period. The current injected into the multiple active layers during the current decrease period is lower than the current injected into the multiple active layers during the current injection period.

According to Aspect 2, the surface emitting laser of Aspect 1, further includes: a first refractive index region having a first refractive index; and a second refractive index region surrounding the first refractive index region and having a second refractive index lower than the first refractive index of the first refractive index region. The first refractive index region and the second refractive index region are in the same layer.

According to Aspect 3, in the surface emitting laser of Aspect 2, the second refractive index region is formed by oxidation confinement. The first refractive index region has a first thickness of 35 nm or less. The second refractive index region has a second thickness that is twice or less of the first thickness at a position of 3 μm from a tip end portion of a boundary between the first refractive index region and the second refractive index region.

According to Aspect 4, in the surface emitting laser of Aspect 2 or 3, according to claim 2 or 3, an area of a region surrounded by a tip end portion of a boundary between the first refractive index region and the second refractive index region in the same layer is 120 μm² or less.

According to Aspect 5, in the surface emitting laser of Aspect 2, the first refractive index region and the second refractive index region are formed by buried tunnel junction.

According to Aspect 6, the surface emitting laser of any one of Aspect 1 to Aspect 5, further includes: a multi-quantum well structure including multiple semiconductor layers in an optical path of a laser beam emitted from the multiple active layers and the multiple reflectors; and another electrode pair connected to another power supply device and configured to apply an electric field to the multi-quantum well structure in a direction orthogonal to a well surface of the multiple-quantum well structure. The surface emitting laser does not oscillate a laser beam during an electric-field application period in which said another power supply device applies the electric field to the multiple-quantum well structure; and oscillates the laser beam during an electric-field decrease period after the electric-field application period. The electric field applied to the multi-quantum well structure during the electric-field decrease period is lower than the electric field applied to the multi-quantum well structure during the electric-field application period.

According to Aspect 7, in the surface emitting laser of Aspect 1, the multiple reflectors include: a first reflector on one end face of the multiple active layers; and a second reflector on another end face of the multiple active layers. The multi-quantum well structure is on said one end face of the multiple active layers.

According to Aspect 8, in the surface emitting laser of Aspect 7, the first reflector is cylindrical, and one electrode of said another electrode pair is at least partly at a central portion of the first reflector in a direction parallel to a well surface.

According to Aspect 9, a laser device includes the surface emitting laser of any one of Aspect 6 to Aspect 8. The power supply device is connected to the electrode pair and configured to inject the current into the surface emitting laser.

According to Aspect 10, a laser device include: the surface emitting laser of any one of Aspect 6 to Aspect 8; the power supply device connected to the electrode pair; and said another power supply device connected to said another electrode pair.

According to Aspect 11, in the laser device of Aspect 10, the electric-field application period starts before a start of the current injection period.

According to Aspect 12, in the laser device of Aspect 10 or 11, the current decrease period starts at the same time as or after a start of the electric-field decrease period.

According to Aspect 13, in the surface emitting laser of any one of Aspect 1 to Aspect 12, wherein the surface emitting laser outputs a light pulse, a time width of which is shorter than the current injection period.

According to Aspect 14, in the laser device of any one of claims 9 to 13, the current injection period and the current decrease period are repeated multiple times, and a ratio of the current injection period to the current decrease period is 0.5% or less.

According to Aspect 15, a detection device includes: the laser device of any one of Aspect 9 to Aspect 14; and a detector configured to detect light emitted from the surface emitting laser and reflected by an object.

According to Aspect 17, the detection device of Aspect 15, the detection device calculates a distance to the object based on a signal output from the detector.

According to Aspect 18, a mobile object comprising the detection device of Aspect 15 or 16.

The above-described embodiments are illustrative and do not limit the present invention. Thus, numerous additional modifications and variations are possible in light of the above teachings. For example, elements and/or features of different illustrative embodiments may be combined with each other and/or substituted for each other within the scope of the present invention.

This patent application is based on and claims priority to Japanese Patent Application No. 2022-011032, filed on Jan. 27, 2022, in the Japan Patent Office, the entire disclosure of which is hereby incorporated by reference herein.

### REFERENCE SIGNS LIST

30 Resonator
31, 37 Spacer layer
32, 34, 36 Active layer
33, 35 Tunnel junction
120 N-type DBR
140, 441, 442 P-type DBR
150 Oxidized confinement layer
151 Oxidized region
152 Non-oxidized region
160 Upper electrode
170 Lower electrode
180, 280, 380, 480 Mesa
300, 400, 500, 600, 700, 800, 900, 1000 Surface emitting laser
450, 850 BTJ region
451 P-type layer
452 N-type layer
541 First p-type DBR
542 Second p-type DBR
580 Mesa post
581 First power supply device
582 Second power supply device
590 Multiple-quantum well structure
1100 Automobile (mobile object)
1300 Laser device
1400 Distance measurement device

1. A surface emitting laser, comprising:
multiple active layers;
a resonator including a tunnel junction between the multiple active layers;
multiple reflectors sandwiching the resonator between the multiple reflectors; and
an electrode pair connected to a power supply through which a current is injected into the multiple active layers,
wherein the surface emitting laser:
does not oscillate a laser beam during a current injection period in which the power supply injects the current into the multiple active layers through the electrode pair; and
oscillates the laser beam during a current decrease period after the current injection period, and
the current injected into the multiple active layers during the current decrease period is lower than the current injected into the multiple active layers during the current injection period.

2. The surface emitting laser according to claim 1, further comprising:
a first refractive index region having a first refractive index; and
a second refractive index region surrounding the first refractive index region and having a second refractive index lower than the first refractive index of the first refractive index region, and
the first refractive index region and the second refractive index region are in a same layer.

3. The surface emitting laser according to claim 2, wherein:
the second refractive index region is formed by oxidation confinement,
the first refractive index region has a first thickness of 35 nm or less, and
the second refractive index region has a second thickness that is twice or less of the first thickness at a position of 3 μm from a tip end portion of a boundary between the first refractive index region and the second refractive index region.

4. The surface emitting laser according to claim 2,
wherein an area of a region surrounded by a tip end portion of a boundary between the first refractive index region and the second refractive index region in the same layer is 120 μm² or less.

5. The surface emitting laser according to claim 2,
wherein the first refractive index region and the second refractive index region are formed by buried tunnel junction.

6. The surface emitting laser according to claim 1, further comprising:
a multi-quantum well structure including multiple semiconductor layers in an optical path of a laser beam emitted from the multiple active layers and the multiple reflectors; and
another electrode pair connected to another power supply and to apply an electric field to the multi-quantum well structure in a direction orthogonal to a well surface of the multiple-quantum well structure,
wherein the surface emitting laser:
does not oscillate a laser beam during an electric-field application period in which said another power supply applies the electric field to the multiple-quantum well structure; and
oscillates the laser beam during an electric-field decrease period after the electric-field application period,
the electric field applied to the multi-quantum well structure during the electric-field decrease period is lower than the electric field applied to the multi-quantum well structure during the electric-field application period.

7. The surface emitting laser according to claim 6, wherein the multiple reflectors include:
a first reflector on one end face of the multiple active layers; and
a second reflector on another end face of the multiple active layers, and
the multi-quantum well structure is on said one end face of the multiple active layers.

8. The surface emitting laser according to claim 7, wherein:
the first reflector is cylindrical, and
one electrode of said another electrode pair is at least partly at a central portion of the first reflector in a direction parallel to the well surface.

9. A laser device comprising:
the surface emitting laser according to claim 1;
wherein the power supply is connected to the electrode pair and is to inject the current into the surface emitting laser.

10. A laser device comprising:
the surface emitting laser according to claim 6,
the power supply connected to the electrode pair; and
said another power supply connected to said another electrode pair.

11. The laser device according to claim 10,
wherein the electric-field application period starts before a start of the current injection period.

12. The laser device according to claim 10,
wherein the current decrease period starts at a same time as or after a start of the electric-field decrease period.

13. The surface emitting laser according to claim 9,
wherein the surface emitting laser outputs a light pulse, a time width of which is shorter than the current injection period.

14. The laser device according to claim 9, wherein:
the current injection period and the current decrease period are repeated multiple times, and
a ratio of the current injection period to the current decrease period is 0.5% or less.

15. A detection device comprising:
the laser device according to claim 9; and
a detector to detect light emitted from the surface emitting laser and reflected by an object.

16. The detection device according to claim 15,
wherein the detector calculates a distance to the object based on a signal output from the detector.

17. A mobile object comprising the detection device according to claim 15.

18. The surface emitting laser according to claim 10,
wherein the surface emitting laser outputs a light pulse, a time width of which is shorter than the current injection period.

19. The laser device according to claim 10, wherein:
the current injection period and the current decrease period are repeated multiple times, and
a ratio of the current injection period to the current decrease period is 0.5% or less.
